(19) United States
(12) Patent Application Publication
(10) Pub. No.: US 2025/0151615 A1
(43) Pub. Date: May 8, 2025

(54) DISPLAY APPARATUS

(71) Applicant: Samsung Display Co., Ltd., Yongin-si (KR)

(72) Inventors: Jinsoo Jung, Yongin-si (KR); Soungwook Kim, Yongin-si (KR); Junyong Shin, Yongin-si (KR); Seokgyu Yoon, Yongin-si (KR); Junyoung Lee, Yongin-si (KR); Minsoo Choi, Yongin-si (KR)

(21) Appl. No.: 18/938,163

(22) Filed: Nov. 5, 2024

(30) Foreign Application Priority Data
Nov. 6, 2023 (KR) 10-2023-0151937

(51) Int. Cl. H10K 85/60; H10K 30/20; H10K 39/34

(52) U.S. Cl. CPC H10K 85/6572; H10K 85/653; H10K 85/654; H10K 85/655; H10K 85/6574; H10K 30/20; H10K 39/34

(57) ABSTRACT

A display apparatus includes a substrate including an emission area and a sensing area, a light-emitting device on the substrate corresponding to the emission area, and a light-receiving device on the substrate corresponding to the sensing area. The light-emitting device includes a pixel electrode, a lower emission layer on the pixel electrode, an upper emission layer on the lower emission layer, and an opposite electrode on the upper emission layer. The light-receiving device includes a sensing electrode, an active layer and a sub-charge generation layer on the sensing electrode, and an opposite electrode on the active layer and the sub-charge generation layer.

### CROSS-REFERENCE TO RELATED APPLICATION

The present application claims priority to and the benefit of Korean Patent Application No. 10-2023-0151937, filed on Nov. 6, 2023, in the Korean Intellectual Property Office, the entire content of which is incorporated herein by reference.

### BACKGROUND

### 1. Field

Embodiments of the present disclosure described herein are related to a structure of a display apparatus.

### 2. Description of the Related Art

In general, display apparatuses have light-emitting devices (e.g., organic light-emitting diodes) and thin-film transistors formed on a substrate and are operated by causing the light-emitting devices to emit light (e.g., to display an image).

For example, each pixel of a display apparatus has a light-emitting device (e.g., an organic light-emitting diode) with an intermediate layer including an emission layer between a pixel electrode and an opposite electrode. Display apparatuses generally control light emission of each pixel and/or control the degree of light emission through thin-film transistors electrically connected to pixel electrodes. Some layers included in an intermediate layer region (e.g., an intermediate layer) of a light-emitting device may be provided in a plurality of light-emitting devices.

### SUMMARY

Aspects according to one or more embodiments of the present disclosure are directed toward a display apparatus with improved detection performance while implementing images with excellent or suitable quality. However, this is only an example and the scope of the disclosure is not limited thereby.

Additional aspects will be set forth in part in the description which follows and, in part, will be apparent from the description, or may be learned by practice of the presented embodiments of the disclosure.

According to one or more embodiments, a display apparatus includes a substrate including an emission area and a sensing area, a light-emitting device arranged on the substrate to correspond to the emission area, and a light-receiving device arranged on the substrate to correspond to the sensing area, wherein the light-emitting device includes a pixel electrode, a lower emission layer arranged on the pixel electrode, an upper emission layer arranged on the lower emission layer, and an opposite electrode arranged on the upper emission layer, and the light-receiving device includes a sensing electrode, an active layer and a sub-charge generation layer arranged on the sensing electrode, and an opposite electrode arranged on the active layer and the sub-charge generation layer.

According to one or more embodiments, the sub-charge generation layer may be arranged on the active layer.

According to one or more embodiments, the lower emission layer may be arranged on substantially a same layer as the active layer (e.g., may be arranged on and/or be part of the same layer forming the active layer), and the upper emission layer may be arranged on substantially a same layer as the sub-charge generation layer (e.g., may arranged on and/or be part of the same layer forming the sub-charge generation layer).

According to one or more embodiments, the active layer may be arranged on the sub-charge generation layer.

According to one or more embodiments, the lower emission layer may be arranged on substantially a same layer as the sub-charge generation layer (e.g., may be arranged on and/or be part of the same layer forming the sub charge generation layer), and the upper emission layer may be arranged on substantially a same layer as the active layer (e.g., may be arranged on and/or be part of the same layer forming the active layer).

According to one or more embodiments, the sub-charge generation layer may include a p-type or kind sub-charge generation layer and an n-type or kind sub-charge (e.g., n sub-charge) generation layer arranged on the p-type or kind sub-charge (e.g., p sub-charge) generation layer.

According to one or more embodiments, the lower emission layer and the upper emission layer may be patterned for each light-emitting device, and the active layer and the sub-charge generation layer may be patterned for each light-receiving device.

According to one or more embodiments, the display apparatus may further include a main charge generation layer between the lower emission layer and the upper emission layer and between the active layer and the sub-charge generation layer.

According to one or more embodiments, the main charge generation layer may include an n-type or kind main charge (e.g., n main charge) generation layer and a p-type or kind (e.g., (e.g., p charge) main charge generation layer arranged on the n-type or kind main charge generation layer.

According to one or more embodiments, the n-type or kind main charge generation layer may be integrally formed as a single body on an entire surface of the substrate, and the p-type or kind main charge generation layer may be patterned for each of the light-emitting device and the light-receiving device.

According to one or more embodiments, the display apparatus may further include a first hole transport layer between the pixel electrode and the lower emission layer and between the sensing electrode and the active layer, wherein the first hole transport layer may be integrally formed as a single body on an entire surface of the substrate.

According to one or more embodiments, the display apparatus may further include a lower auxiliary layer between the first hole transport layer and the lower emission layer and between the first hole transport layer and the active layer, wherein the lower auxiliary layer may be patterned for each of the light-emitting device and the light-receiving device.

According to one or more embodiments, the display apparatus may further include a second hole transport layer between the main charge generation layer and the upper emission layer and between the main charge generation layer and the sub-charge generation layer, wherein the second hole transport layer may be patterned for each of the light-emitting device and the light-receiving device.

According to one or more embodiments, the display apparatus may further include an upper auxiliary layer between the second hole transport layer and the upper emission layer and between the second hole transport layer and the sub-charge generation layer, wherein the upper auxiliary layer may be patterned for each of the light-emitting device and the light-receiving device.

According to one or more embodiments, the display apparatus may further include a buffer layer and an electron transport layer between the upper emission layer and the opposite electrode and between the sub-charge generation layer and the opposite electrode, wherein the buffer layer and the electron transport layer may be integrally formed as a single body on an entire surface of the substrate.

According to one or more embodiments, the active layer may include a p-type or kind (e.g., p) semiconductor compound and an n-type or kind (e.g., n) semiconductor compound.

According to one or more embodiments, the p-type or kind semiconductor compound may include or be a compound represented by Formula 1:

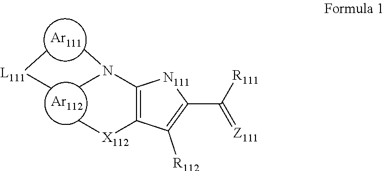

In Formula 1,
Ar₁₁₁ and Ar₁₁₂ may each independently be a C₆-C₃₀ arylene group unsubstituted or substituted with at least one R₁₀ₐ or a C₃-C₃₀ heteroarylene group unsubstituted or substituted with at least one R₁₀ₐ,
X₁₁₁ may be (e.g., selected from among) —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and/or —Ge(Q₁₁₁)(Q₁₁₂)-,
X₁₁₂ and L₁₁₁ may each be (e.g., selected from among) —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and/or —(C(Q₁₁₁)=N)—,
when L₁₁₁ is (e.g., selected from among) —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and/or —(C(Q₁₁₁)=N)—, L₁₁₁ may optionally be connected to Ar₁₁₁ or Ar₁₁₂ to form (or provide) a condensed ring,
Z₁₁₁ may be a C₆-C₃₀ carbocyclic group having at least one functional group (e.g., selected from among) C═O, C═S, C═Se, and/or C═Te and unsubstituted or substituted with at least one R₁₀ₐ or a C₁-C₃₀ heterocyclic group having at least one functional group (e.g., selected from among) C═O, C═S, C═Se, and/or C═Te and substituted or unsubstituted with at least one R₁₀ₐ,
R₁₁₁ to R₁₁₆ may each independently be hydrogen, deuterium, a halogen, a cyano group, a nitro group, a hydroxyl group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, a C₂-C₃₀ acyl group unsubstituted or substituted with at least one R₁₀ₐ, or a (e.g., any suitable) combination thereof,
R₁₀ₐ may be (e.g., selected from among):
deuterium (-D), —F, —Cl, —Br, —I, a hydroxyl group, a cyano group, a nitro group, or a (e.g., any suitable) combination thereof;
a C₁-C₃₀ alkyl group, a C₂-C₃₀ alkenyl group, a C₂-C₃₀ alkynyl group, and/or a C₁-C₃₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₃₀ aryloxy group, a C₆-C₃₀ arylthio group, a C₁-C₆₀ heteroaryloxy group, a C₁-C₃₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof,
wherein Q₁₁ to Q₁₃, Q₂₁ to Q₂₃, Q₃₁, Q₃₂, Q₁₁₁, and Q₁₁₂ may each independently be (e.g., selected from among): hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or a (e.g., any suitable) combination thereof.

According to one or more embodiments, Z₁₁₁ of Formula 1 may be represented by one of (e.g., selected from among) Formulae 111A to 111F:

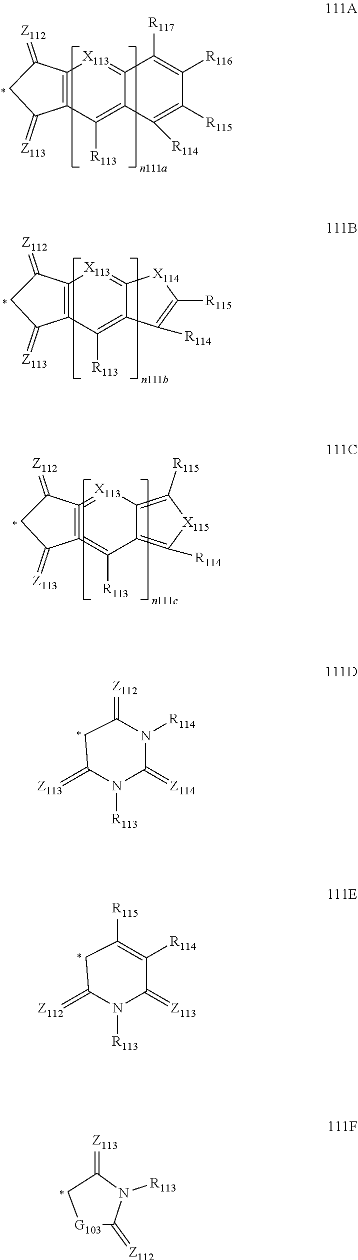

In Formulae 111A to 111F,
Z₁₁₂ to Z₁₁₄ may each be O, S, Se, or Te,
X₁₁₃ may be N or C(Q₁₁₃),
X₁₁₄ and X₁₁₅ may each independently be O, S, Se, Te, Si(Q₁₁₁)(Q₁₁₂), or Ge(Q₁₁₁)(Q₁₁₂),
n₁₁₁ₐ to n_{111c} may each be an integer from 0 to 3,
R₁₁₃ to R₁₁₇ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof, and
definitions of Q₁₁₁ to Q₁₁₃ may be a same as a definition of Q₁₁₁ described previously.

According to one or more embodiments, the n-type or kind semiconductor compound may include or be a compound represented by (e.g., selected from among) Formula 2 or 3:

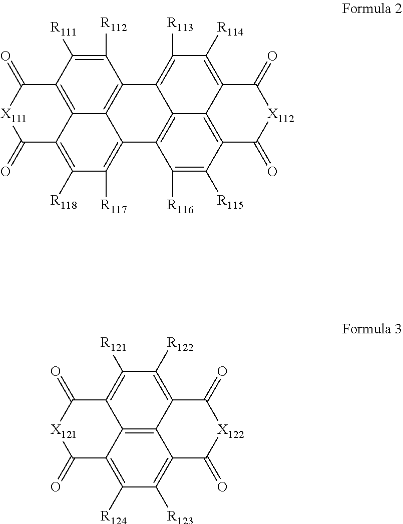

wherein, in Formula 2,
X₁₁₁ and X₁₁₂ may each independently be O or NR₁₁₉, and
R₁₁₁ to R₁₁₉ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof,
wherein, in Formula 3,
X₁₂₁ and X₁₂₂ may each independently be O or NR₁₂₅, and
R₁₂₁ to R₁₂₅ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof,
wherein, in Formulae 2 and 3,
R₁₀ₐ may be (e.g., selected from among):
deuterium (-D), —F, —Cl, —Br, —I, a hydroxyl group, a cyano group, or a nitro group, or a (e.g., any suitable) combination thereof;
a C₁-C₆₀ alkyl group, a C₂-C₆₀ alkenyl group, a C₂-C₆₀ alkynyl group, and/or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof,
wherein Q₁₁ to Q₁₃, Q₂₁ to Q₂₃, Q₃₁, and Q₃₂ may each independently be (e.g., selected from among): hydrogen; deuterium; —F; —Cl; —Br; —I; a hydroxyl group; a cyano group; a nitro group; a C₁-C₃₀ alkyl group; a C₂-C₃₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, and/or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or a (e.g., any suitable) combination thereof.

According to one or more embodiments, the n-type or kind semiconductor compound may include or be one of the following compounds (e.g., selected from among the following compounds):

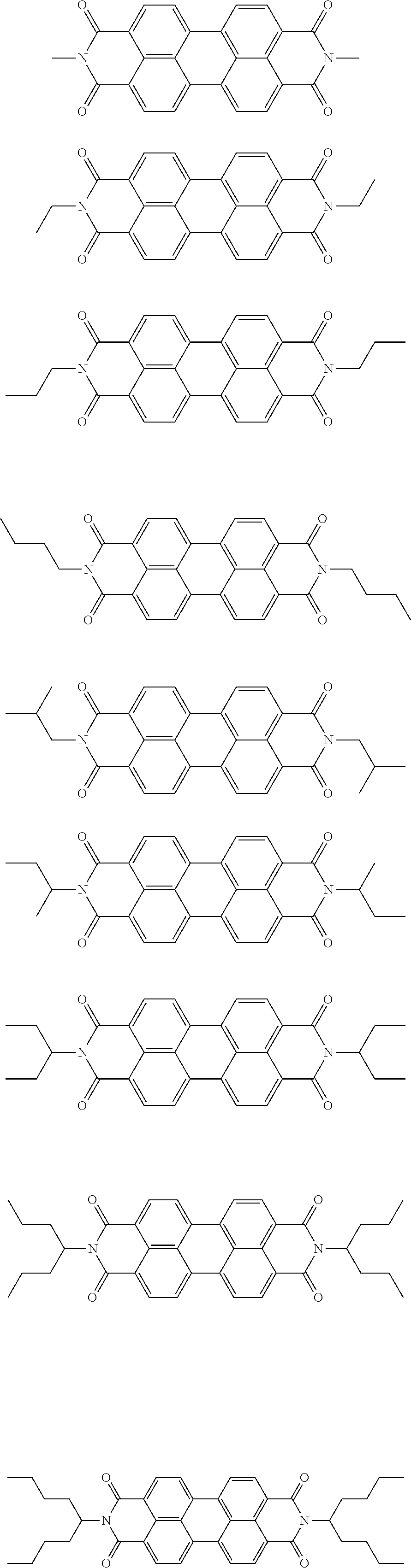

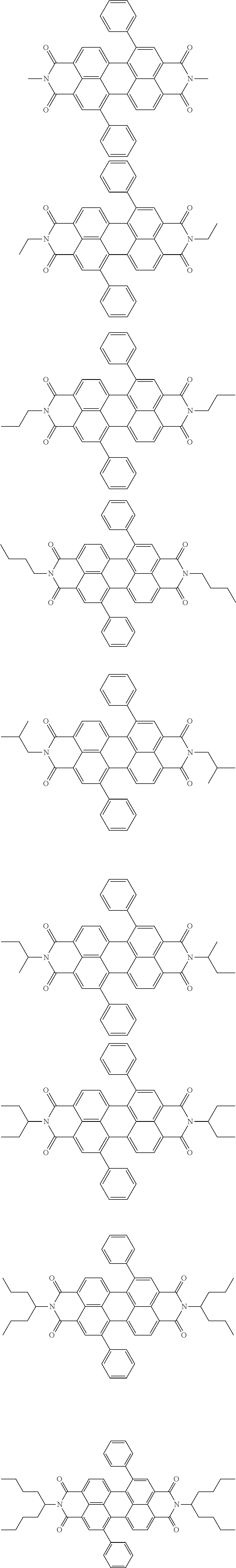

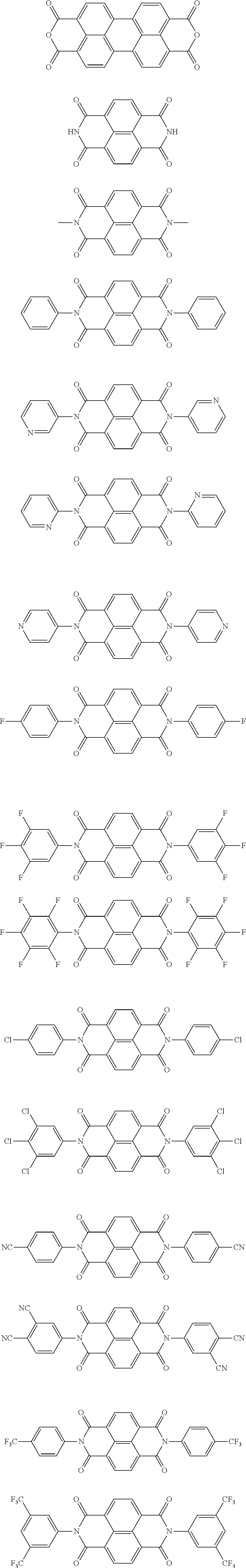

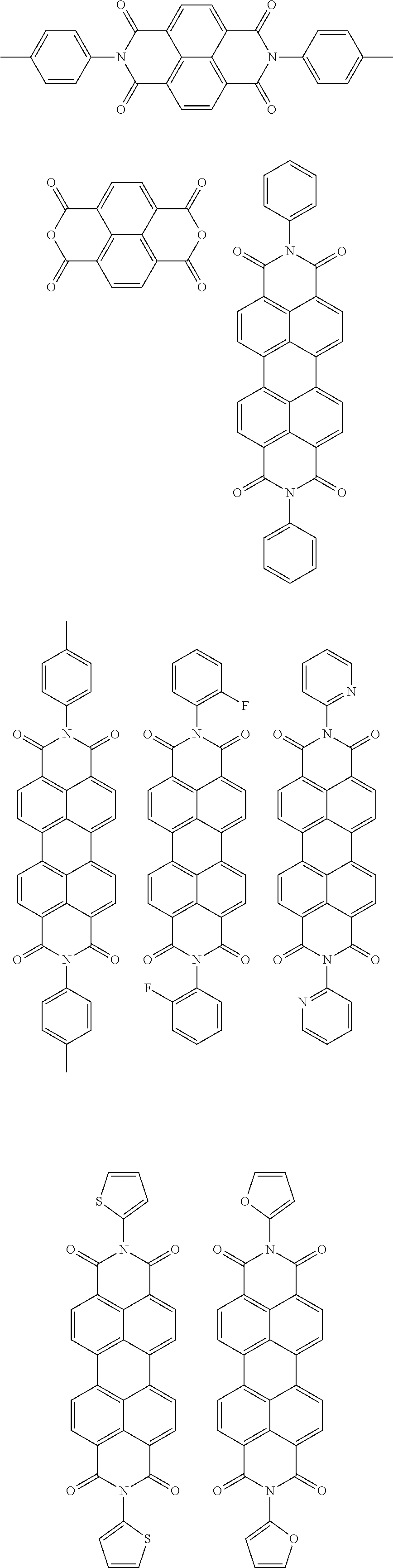

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a portion of a display apparatus, according to one or more embodiments;

FIG. 2 is a schematic cross-sectional view of a display apparatus according to one or more embodiments;

FIG. 3 is an equivalent circuit diagram of a pixel circuit electrically connected to a light-emitting device and a sensor circuit electrically connected to a light-receiving device in a display apparatus, according to one or more embodiments;

FIG. 4 is a plan view schematically illustrating a portion of a display apparatus, according to one or more embodiments;

FIG. 5 is a cross-sectional view schematically illustrating a portion of a display apparatus, according to one or more embodiments;

FIG. 6 is a conceptual diagram schematically illustrating a portion of a display apparatus, according to one or more embodiments;

FIG. 7 is a graph showing comparison of external quantum efficiency (EQE) according to a wavelength between a display apparatus according to a comparative example and a display apparatus according to an example;

FIG. 8 is a cross-sectional view schematically illustrating a portion of a display apparatus, according to one or more embodiments; and

FIG. 9 is a conceptual diagram schematically illustrating a portion of a display apparatus, according to one or more embodiments.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described herein, by referring to the drawings, to explain aspects of the present description. As utilized herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

As used herein, the singular forms “a,” “an” and “the” are intended to include the plural forms as well, unless the context clearly indicates otherwise.

In present disclosure, “not including a or any ‘component” “excluding a or any ‘component”, “component’-free”, and/or the like refers to that the “component” not being added, selected or utilized as a component in the composition/structure, but the “component” of less than a suitable amount may still be included due to other impurities and/or external factors.

In the present disclosure, when dot, dots or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As the present description allows for one or more suitable changes and numerous embodiments, certain embodiments will be illustrated in the drawings and described in more detail in the written description. Effects and features of the disclosure, and methods of achieving them will be clarified with reference to embodiments described in more detail with reference to the drawings. However, the disclosure is not limited to the following embodiments and may be embodied in one or more suitable forms.

Hereinafter, embodiments will be described in more detail with reference to the accompanying drawings. When describing embodiments with reference to the accompanying drawings, the same or corresponding elements are denoted by the same reference numerals.

It will be understood that although the terms “first,” “second,” and/or the like may be utilized herein to describe one or more suitable elements, these elements should not be limited by these terms. These terms are only utilized to distinguish one element from another.

The singular forms as utilized herein are intended to include the plural forms as well unless the context clearly indicates otherwise.

It will be further understood that the terms “include” and/or “comprise” utilized herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. For example, for example, intervening layers, regions, or elements may be present therebetween.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When a certain embodiment may be implemented differently, a specific process order may be performed differently from the stated order. For example, two consecutively described processes may be performed substantially at the same time or performed in an order opposite to the described order.

It will be further understood that, when layers, regions, or components are referred to as being connected to each other, they may be directly connected to each other or indirectly connected to each other with intervening layers, regions, or components therebetween. For example, when layers, regions, or elements are referred to as being electrically connected to each other, they may be directly electrically connected to each other or indirectly electrically connected to each other with intervening layers, regions, or elements therebetween.

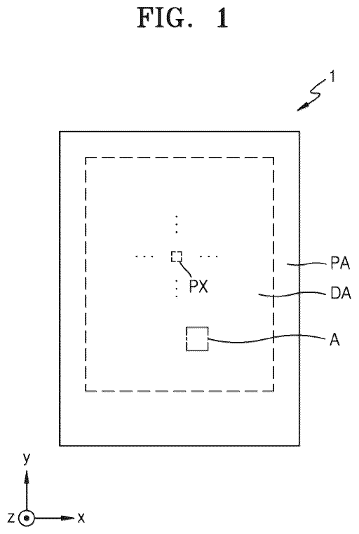

FIG. 1 is a plan view schematically illustrating a portion of a display apparatus 1, according to one or more embodiments.

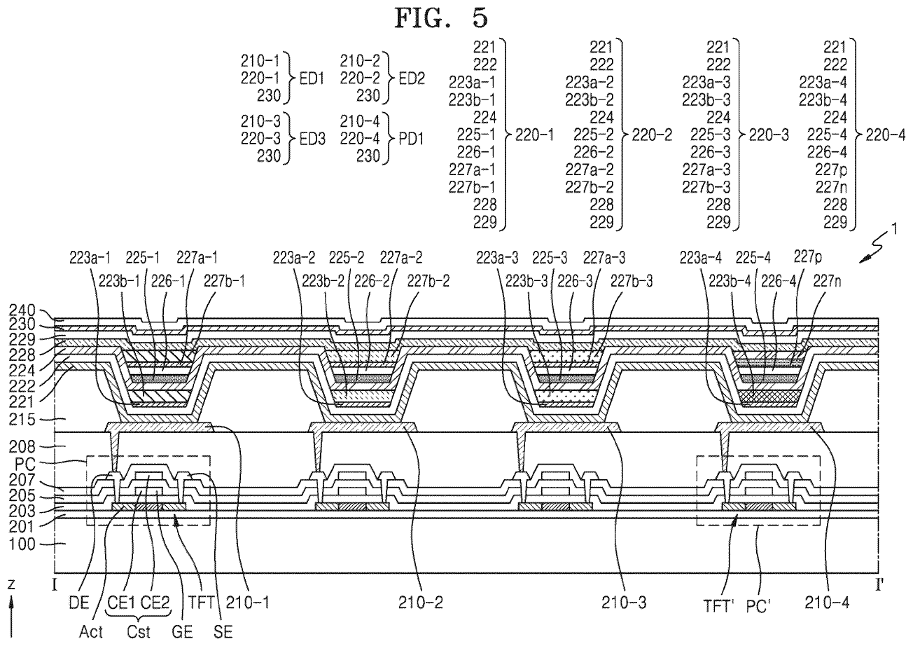

Referring to FIG. 1, the display apparatus 1 may include a display area DA in which a plurality of pixels PX are arranged and a peripheral area PA outside the display area DA. For example, the peripheral area PA may completely surround the display area DA. It may be understood that a substrate (see 100 of FIG. 5) included in the display apparatus 1 has the display area DA and the peripheral area PA.

Each of the pixels PX of the display apparatus 1 refers to a minimum unit for displaying an image, and the display apparatus 1 may display a desired or suitable image through a combination of the pixels PX. For example, the pixels PX may be configured to emit pieces (e.g., rays) of light of certain colors, and the display apparatus 1 may display a desired or suitable image by the pieces of light emitted from the pixels PX. For example, each of the pixels PX may be configured to emit red light, green light, or blue light. Each of the pixels PX may include a light-emitting device, such as an organic light-emitting diode. The pixel PX may be connected to a pixel circuit including thin-film transistors (TFT) and storage capacitors.

The display area DA may have a polygonal shape including a rectangular shape, as illustrated in FIG. 1. For example, the display area DA may have a rectangular shape with a horizontal length longer than a vertical length, a rectangular shape with a horizontal length (e.g., length) shorter than a vertical length (e.g., width), or a square shape. In one or more embodiments, the display area DA may have other shapes, such as an elliptical shape or a circular shape.

The peripheral area PA may be a non-display area in which pixels PX are not arranged. A driver and/or the like configured to provide electrical signals and/or power to the pixels PX may be arranged in the peripheral area PA. Pads, to which one or more suitable electronic devices or a printed circuit board may be electrically connected, may be arranged in the peripheral area PA. The pads may be apart from each other in the peripheral area PA and may be electrically connected to a printed circuit board or integrated circuit devices.

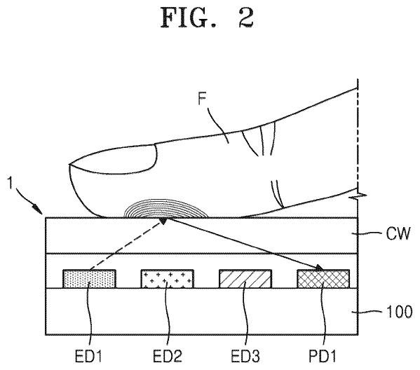

FIG. 2 is a schematic cross-sectional view of a display apparatus 1 according to one or more embodiments.

Referring to FIG. 2, the display apparatus 1 according to one or more embodiments may further include an optical sensor as well as a plurality of pixels (see PX of FIG. 1). Each of the pixels (see PX of FIG. 1) may include at least one of a first light-emitting device ED1, a second light-emitting device ED2, and a third light-emitting device ED3, and the optical sensor may include a first light-receiving device PD1. The first light-emitting device ED1, the second light-emitting device ED2, and the third light-emitting device ED3 may be configured to externally emit different pieces (e.g., rays) of light. For example, the first light-emitting device ED1 may be configured to externally emit green light, the second light-emitting device ED2 may be configured to externally emit red light, and the third light-emitting device ED3 may be configured to externally emit blue light.

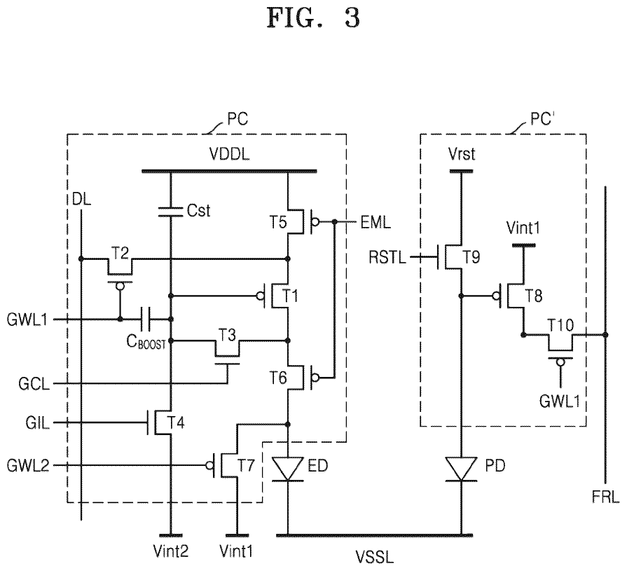

As illustrated in FIG. 3, the display apparatus 1 may have a function of sensing an object in contact with a cover window CW, for example, a fingerprint of a finger F. Among the pieces of light emitted from at least one of the first light-emitting device ED1, the second light-emitting device ED2, or the third light-emitting device ED3, at least a portion of reflected light reflected from a user's fingerprint may be re-incident on the first light-receiving device PD1, and thus, the first light-receiving device PD1 may be configured to detect the reflected light. For example, the green light emitted by the first light-emitting device ED1 may be reflected from the object in contact with the cover window CW and may be re-incident on the first light-receiving device PD1, and thus, the first light-receiving device PD1 may be configured to detect the re-incident green light.

FIG. 3 is an equivalent circuit diagram of a pixel circuit electrically connected to a light-emitting device and a sensor circuit electrically connected to a light-receiving device in a display apparatus, according to one or more embodiments.

Referring to FIG. 3, the pixel (see PX of FIG. 1) may include a light-emitting device ED and a pixel circuit PC configured to control the amount of light emitted from the light-emitting device ED. An optical sensor may include a light-receiving device PD and a sensor circuit PC′ configured to control the amount of light received by the light-receiving device PD.

The pixel circuit PC may be connected to a scan initiation line GIL, a scan control line GCL, a first scan write line GWL1, a second scan write line GWL2, an emission line EML, and a data line DL. In one or more embodiments, the pixel circuit PC may be connected to a first driving voltage line VDDL to which a first driving voltage is applied, a second driving voltage line VSSL to which a second driving voltage is applied, a first initialization voltage line to which a first initialization voltage Vint1 is applied, and a second initialization voltage line to which a second initialization voltage Vint2 is applied.

The sensor circuit PC′ may be connected to the first scan write line GWL1, a reset line RSTL, and a fingerprint detection line FRL. In one or more embodiments, the sensor circuit PC′ may be connected to the second driving voltage line VSSL to which a second driving voltage is applied, a reset voltage line to which a reset voltage Vrst is applied, and the first initialization voltage line to which a first initialization voltage Vint1 is applied.

The pixel circuit PC may include a plurality of transistors and at least one capacitor and may be connected to the light-emitting device ED. The transistors may include first to seventh transistors T1, T2, T3, T4, T5, T6, and T7. Among the transistors, the first transistor T1 may be a driving transistor and the second to seventh transistors T2-T7 may be switching transistors configured to be turned on or off in response to scan signals applied to gate electrodes thereof.

The first transistor T1 may include a gate electrode, a first electrode, and a second electrode. The gate electrode of the first transistor T1 may be connected to a first electrode of the third transistor T3 and one electrode of a storage capacitor Cst. The first electrode of the first transistor T1 may be connected to a second electrode of the second transistor T2 and a second electrode of the fifth transistor T5. The second electrode of the first transistor may be connected to a second electrode of the third transistor T3 and a first electrode of the sixth transistor T6.

The light-emitting device ED may be configured to emit light according to a driving current. The amount of light emitted from the light-emitting device ED may be proportional to the driving current. The light-emitting device ED may be an organic light-emitting diode including a pixel electrode, an opposite electrode, and an organic emission layer between the pixel electrode and the opposite electrode. In one or more embodiments, the light-emitting device ED may be an inorganic light-emitting diode including an inorganic emission layer between a pixel electrode and an opposite electrode, or may be a quantum dot light-emitting diode including a quantum dot emission layer between a pixel electrode and an opposite electrode. Additionally, the light-emitting device ED may be a micro light-emitting diode. The pixel electrode of the light-emitting device ED may be connected to a second electrode of the sixth transistor T6 and a second electrode of the seventh transistor T7, and the opposite electrode may be connected to the second driving voltage line VSSL.

The second transistor T2 may be configured to be turned on in response to the scan signal of the first scan write line GWL1 and connect the first electrode of the first transistor T1 to the data line DL. The gate electrode of the second transistor T2 may be connected to the first scan write line GWL1, the first electrode of the second transistor T2 may be connected to the data line DL, and the second electrode of the second transistor T2 may be connected to the first electrode of the first transistor T1.

The third transistor T3 may be configured to be turned on in response to the scan signal of the scan control line GCL and connect the gate electrode of the first transistor T1 to the second electrode of the first transistor T1. For example, when the third transistor T3 is turned on, the gate electrode of the first transistor T1 is connected to the second electrode of the first transistor T1, and thus, the first transistor T1 may operate as a diode. The gate electrode of the third transistor T3 may be connected to the scan control line GCL, the second electrode of the third transistor T3 may be connected to the second electrode of the first transistor T1, and the first electrode of the third transistor T3 may be connected to the gate electrode of the first transistor T1. The fourth transistor T4 may be configured to be turned on in response to the scan signal of the scan initiation line GIL and connect the gate electrode of the first transistor T1 to the second initialization voltage line. In this case, the gate electrode of the first transistor T1 may be discharged to the second initialization voltage Vint2 of the second initialization voltage line. The gate electrode of the fourth transistor T4 may be connected to the scan initiation line GIL, the first electrode of the fourth transistor T4 may be connected to the second initialization voltage line, and the second electrode of the fourth transistor T4 may be connected to the gate electrode of the first transistor T1.

The fifth transistor T5 may be configured to be turned on in response to an emission signal of the emission line EML and connect the first electrode of the first transistor T1 to the first driving voltage line VDDL. The gate electrode of the fifth transistor T5 may be connected to the emission line EML, the first electrode of the fifth transistor T5 may be connected to the first driving voltage line VDDL, and the second electrode of the fifth transistor T5 may be connected to the first electrode of the first transistor T1.

The sixth transistor T6 may be configured to be turned on in response to the emission signal of the emission line EML and connect the second electrode of the first transistor T1 to the pixel electrode of the light-emitting device ED. The gate electrode of the sixth transistor T6 may be connected to the emission line EML, the first electrode of the sixth transistor T6 may be connected to the second electrode of the first transistor T1, and the second electrode of the sixth transistor T6 may be connected to the pixel electrode of the light-emitting device ED. When both (e.g., simultaneously) the fifth transistor T5 and the sixth transistor T6 are turned on, the driving current may be supplied to the light-emitting device ED.

The seventh transistor T7 may be configured to be turned on in response to the scan signal of the second scan write line GWL2 and connect the first initialization voltage line to the pixel electrode of the light-emitting device ED. In this case, the pixel electrode of the light-emitting device ED may be discharged to the first initialization voltage Vint1. The gate electrode of the seventh transistor T7 may be connected to the second scan write line GWL2, the first electrode of the seventh transistor T7 may be connected to the first initialization voltage line, and the second electrode of the seventh transistor T7 may be connected to the pixel electrode of the light-emitting device ED.

The storage capacitor Cst may be between the gate electrode of the first transistor T1 and the first driving voltage line VDDL. One electrode of the storage capacitor Cst may be connected to the gate electrode of the first transistor T1, and the other electrode of the storage capacitor Cst may be connected to the first driving voltage line VDDL. Due to this, the storage capacitor Cst may maintain the potential difference between the gate electrode of the first transistor T1 and the first driving voltage line VDDL.

A boost capacitor C_{BOOST} may be between the gate electrode of the second transistor T2 and the gate electrode of the first transistor T1. One electrode of the boost capacitor C_{BOOST} may be connected to the first scan write line GWL1 that is connected to the gate electrode of the second transistor T2, and the other electrode of the boost capacitor C_{BOOST} may be connected to the gate electrode of the first transistor T1 and one electrode of the storage capacitor Cst. The boost capacitor C_{BOOST} may be a boosting capacitor. When a signal of the first scan write line GWL1 is a voltage that turns off the second transistor T2, the boost capacitor C_{BOOST} may increase a voltage of a node and decrease a voltage (a black voltage) that displays black.

The sensor circuit PC′ may include a plurality of transistors and may be connected to the light-receiving device PD. The transistors may include eighth to tenth transistors T8, T9, and T10. Among the transistors, the eighth transistor T8 may be a driving transistor and the ninth transistor T9 and the tenth transistor T10 may be switching transistors configured to be turned on or off in response to the reset signal and the scan signal applied to the gate electrodes thereof.

When a plurality of light-emitting devices ED and a plurality of light-receiving devices PD are arranged in a single display apparatus (see 1 of FIG. 1), the voltage lines or signal lines configured to drive the light-emitting devices ED when the light-receiving devices PD are driven may be commonly utilized. For example, by minimizing or reducing the additional arrangement of the voltage lines or signal lines configured to drive the light-receiving devices PD in the display apparatus (see 1 of FIG. 1), the resolution of the display apparatus (see 1 of FIG. 1) may be secured and the peripheral area (see PA of FIG. 1) may be minimized or reduced. For example, the signal line connected to the gate electrode of the second transistor T2 in the pixel (see PX of FIG. 1) may be commonly utilized with the signal line connected to the gate electrode of the tenth transistor T10 in the optical sensor. For example, the gate electrode of the second transistor T2 and the gate electrode of the tenth transistor T10 may be connected to the first scan write line GWL1. As another example, the second driving voltage line VSSL may be a common voltage line connected to the opposite electrode of the light-emitting device ED and the opposite electrode of the light-receiving device PD. As another example, the first initialization voltage line configured through which the first initialization voltage Vint1 is applied may be a common voltage line connected to the second electrode of the eighth transistor T8 and the second electrode of the seventh transistor T7 in the optical sensor.

The light-receiving device PD may be a light-receiving diode including a sensing electrode, an opposite electrode, and a photoelectric conversion layer between the sensing electrode and the opposite electrode. The light-receiving device PD may convert light incident from the outside into an electrical signal. The light-receiving device PD may be a light-receiving diode or a phototransistor including a PN-type or kind or PIN-type or kind inorganic material. In one or more embodiments, the light-receiving device PD may be an organic light-receiving diode including an electron-donating material that generates donor ions and an electron-accepting material that generates acceptor ions.

When the light-receiving device PD is exposed to external light, photocharges may be generated and the generated photocharges may accumulate on the sensing electrode of the light-receiving device PD. In this case, the voltage of the node electrically connected to the sensing electrode may increase. When the light-receiving device PD and the fingerprint detection line FRL are connected to each other according to the turn-on of the eighth transistor T8 and the tenth transistor T10, a current may flow through the fingerprint detection line FRL in proportion to the voltage of the node at which charges accumulate.

The eighth transistor T8 may be turned on in response to the voltage applied to the gate electrode and connect the first electrode of the tenth transistor T10 to the first initialization voltage line to which the first initialization voltage Vint1 is applied. In this case, the second electrode of the tenth transistor T10 may be discharged to the first initialization voltage Vint1. The gate electrode of the eighth transistor T8 may be connected to the node between the ninth transistor T9 and the light-receiving device PD, the first electrode of the eighth transistor T8 may be connected to the first initialization voltage line, and the second electrode of the eighth transistor T8 may be connected to the first electrode of the tenth transistor T10. The eighth transistor T8 may be a source follower amplifier configured to generate a source-drain current in proportion to the amount of charges of the node, which are input to the gate electrode thereof. In another embodiment, the first electrode of the eighth transistor T8 may be connected to the first driving voltage line VDDL or the second initialization voltage line.

The tenth transistor T10 may be turned on in response to the scan signal of the first scan write line GWL1 and connect the second electrode of the eighth transistor T8 to the fingerprint detection line FRL. The fingerprint detection line FRL may be configured to transmit a fingerprint detection signal to a read-out circuit. The gate electrode of the tenth transistor T10 may be connected to the first scan write line GWL1, the first electrode of the tenth transistor T10 may be connected to the second electrode of the eighth transistor T8, and the second electrode of the tenth transistor T10 may be connected to the fingerprint detection line FRL.

The ninth transistor T9 may be turned on in response to the reset signal of the reset line RSTL and reset the node connected to the gate electrode of the eighth transistor T8 to the reset voltage Vrst. The gate electrode of the ninth transistor T9 may be connected to the reset line RSTL, the first electrode of the ninth transistor T9 may be connected to the reset voltage line, and the second electrode of the ninth transistor T9 may be connected to the node connecting the light-receiving device PD to the eighth transistor T8. When the reset driver configured to output the reset signal of the reset line RSTL is not provided, the ninth transistor T9 may be turned on in response to the scan signal.

When the first electrode of each of the first to tenth transistors T1, T2, T3, T4, T5, T6, T7, T8, T9, and T10 is a source electrode, the second electrode thereof may be a drain electrode. In one or more embodiments, when the first electrode of each of the first to tenth transistors T1, T2, T3, T4, T5, T6, T7, T8, T9, and T10 is a drain electrode, the second electrode thereof may be a source electrode.

The active layer of each of the first to tenth transistors T1, T2, T3, T4, T5, T6, T7, T8, T9, and T10 may include one of polycrystalline silicon, amorphous silicon, and an oxide semiconductor. For example, each of the first and second transistors T1 and T2, the fifth to eighth transistors T5, T6, T7, and T8, and the tenth transistor T10 may be a P-type or kind (e.g., p) transistor. In this case, the active layer of each of the first and second transistors T1 and T2, the fifth to eighth transistors T5, T6, T7, and T8, and the tenth transistor T10 may include polysilicon. In one or more embodiments, each of the third transistor T3, the fourth transistor T4, and the ninth transistor T9 may be an N-type or kind (e.g., n) transistor that forms an active layer of an oxide semiconductor.

However, embodiments are not limited thereto, and each of the first to tenth transistors T1, T2, T3, T4, T5, T6, T7, T8, T9, and T10 may be a P-type or kind transistor. As another example, each of the eighth to tenth transistors T8, T9, and T10 may be formed as a P-type or kind transistor.

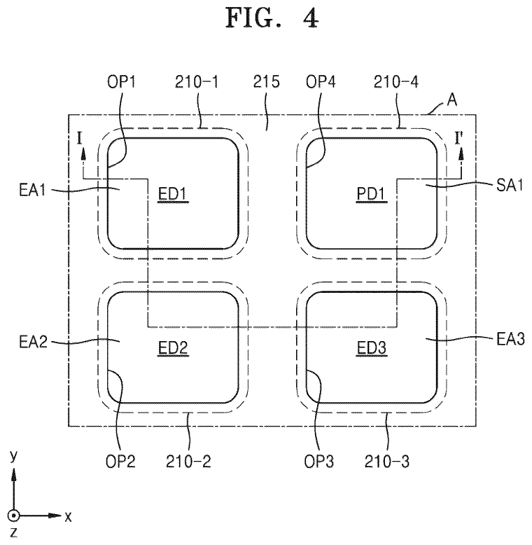

FIG. 4 is a plan view schematically illustrating a portion of a display apparatus, according to an embodiment. For example, FIG. 4 is an enlarged plan view schematically illustrating region A of FIG. 1. FIG. 4 illustrates a plan view on a bank layer 215 for convenience.

Referring to FIG. 4, the display apparatus 1 may include a plurality of light-emitting devices and a plurality of light-receiving devices. The light-emitting devices may include a first light-emitting device ED1, a second light-emitting device ED2, and a third light-emitting device ED3, and the light-receiving devices may include a first light-receiving device PD1. The first light-emitting device ED1, the second light-emitting device ED2, and the third light-emitting device ED3 may be configured to externally emit pieces of light of different colors. For example, the first light-emitting device ED1 may be configured to externally emit green light, the second light-emitting device ED2 may be configured to externally emit red light, and the third light-emitting device ED3 may be configured to externally emit blue light. The red light may be light in a wavelength band of about 580 nanometer (nm) to about 780 nm, the blue light may be light in a wavelength band of about 380 nm to about 495 nm, and the green light may be light in a wavelength band of about 495 nm to about 580 nm. The first light-receiving device PD1 may sense an object by detecting the light emitted from the first light-emitting device ED1, the second light-emitting device ED2, and/or the third light-emitting device ED3 and then reflected from the object.

Each of the light-emitting devices may include a pixel electrode, an opposite electrode, and an intermediate layer therebetween, and each of the light-receiving devices may include a sensing electrode, an opposite electrode, and an intermediate layer therebetween. Accordingly, the first light-emitting device ED1 may include a first pixel electrode 210-1, the second light-emitting device ED2 may include a second pixel electrode 210-2, the third light-emitting device ED3 may include a third pixel electrode 210-3, and the first light-receiving device PD1 may include a first sensing electrode 210-4. The first pixel electrode 210-1, the second pixel electrode 210-2, the third pixel electrode 210-3, and the first sensing electrode 210-4 may be apart from each other on a substrate (see 100 of FIG. 5). In the present specification, the expression “in a plan view” refers to a plane viewed from a direction normal (e.g., perpendicular) to the substrate 100. For example, the expression “A and B apart from each other in a plan view” refers to “A and B apart from each other when viewed from a direction normal (e.g., perpendicular) to the substrate 100.”

The bank layer 215 may be arranged on the first pixel electrode 210-1, the second pixel electrode 210-2, the third pixel electrode 210-3, and the first sensing electrode 210-4 and may cover the edge of each of the first pixel electrode 210-1, the second pixel electrode 210-2, the third pixel electrode 210-3, and the first sensing electrode 210-4. For example, the bank layer 215 may have a first opening OP1 exposing the central portion of the first pixel electrode 210-1, a second opening OP2 exposing the central portion of the second pixel electrode 210-2, a third opening OP3 exposing the central portion of the third pixel electrode 210-3, and a fourth opening OP4 exposing the central portion of the first sensing electrode 210-4.

In some embodiments, the emission layers configured to emit light may be respectively located in the first opening OP1, the second opening OP2, and the third opening OP3 of the bank layer 215. Each of the active layers configured to detect light may be located in the fourth opening OP4 of the bank layer 215. The opposite electrode may be arranged on the emission layers and the active layers. As described above, the stack structure of the pixel electrode, the emission layer, and the opposite electrode may constitute one light-emitting device. In one or more embodiments, as described above, the stack structure of the sensing electrode, the active layer, and the opposite electrode may constitute one light-receiving device. One opening of the bank layer 215 may correspond to one light-emitting device and may define one emission area. In one or more embodiments, one opening of the bank layer 215 may correspond to one light-emitting device and may define one emission area.

For example, an emission layer configured to emit green light may be arranged in the first opening OP1, and thus, the first opening OP1 may define a first emission area EA1. Similarly, an emission layer configured to emit red light may be arranged in the second opening OP2, and thus, the second opening OP2 may define a second emission area EA2. An emission layer configured to emit blue light may be arranged in the third opening OP3, and thus, the third opening OP3 may define a third emission area EA3. In contrast, an active layer configured to detect light may be arranged in the fourth opening OP4, and thus, the fourth opening OP4 may define a first sensing area SA1.

Accordingly, the area of the first opening OP1 may be equal to the area of the first emission area EA1. Of course, the area of the second opening OP2 may be equal to the area of the second emission area EA2, and the area of the third opening OP3 may be equal to the area of the third emission area EA3. The area of the fourth opening OP4 may be equal to the area of the first sensing area SA1.

Each of the first opening OP1, the second opening OP2, the third opening OP3, and the fourth opening OP4 may have a polygonal shape when viewed from a direction (a z-axis direction) normal (e.g., perpendicular) to the substrate (see 100 of FIG. 5). In other words, each of the first emission area EA1, the second emission area EA2, the third emission area EA3, and the first sensing area SA1 may have a polygonal shape when viewed from a direction (the z-axis direction) normal (e.g., perpendicular) to the substrate 100. FIG. 4 illustrates that each of the first emission area EA1, the second emission area EA2, the third emission area EA3, and the first sensing area SA1 has a rectangular shape, specifically a rectangular shape with round corners, when viewed from a direction (the z-axis direction) normal (e.g., perpendicular) to the substrate 100. However, the disclosure is not limited thereto. In other words, each of the first emission area EA1, the second emission area EA2, the third emission area EA3, and the first sensing area SA1 layer may have a circular shape or an elliptical shape when viewed from a direction (the z-axis direction) normal (e.g., perpendicular) to the substrate 100.

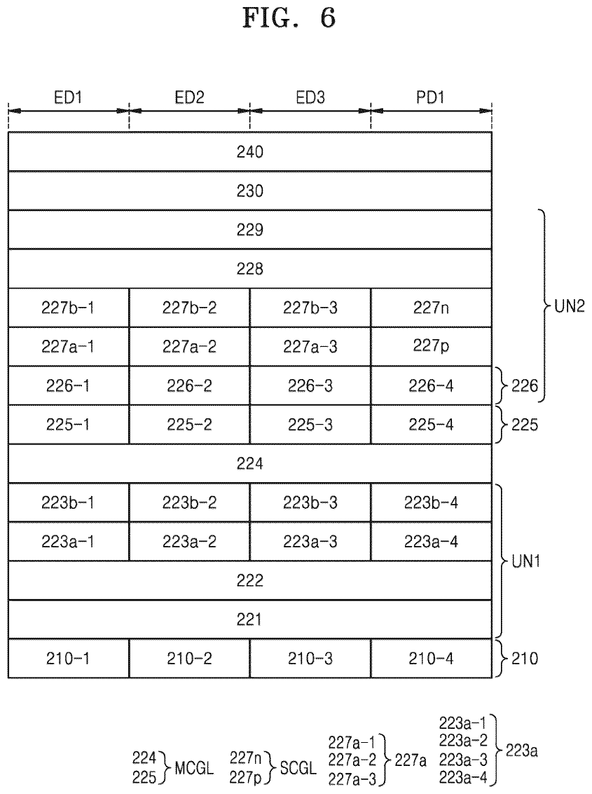

FIG. 5 is a cross-sectional view schematically illustrating a portion of a display apparatus, according to one or more embodiments. For example, FIG. 5 is a schematic cross-sectional view of the display apparatus of FIG. 4 taken along line I-I′ of FIG. 4. FIG. 6 is a conceptual diagram schematically illustrating a portion of a display apparatus, according to one or more embodiments. For example, FIG. 6 is a cross-sectional view schematically illustrating a stack structure of a light-emitting device and a light-receiving device of a display apparatus, according to one or more embodiments.

As illustrated in FIG. 5, a display apparatus 1 according to the present embodiment may include a substrate 100. The substrate 100 may include one or more suitable flexible or bendable materials. For example, the substrate 100 may include glass, metal, or polymer resin. In one or more embodiments, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. Of course, other modifications are possible. For example, the substrate 100 may have a multilayer structure that includes two layers and a barrier layer between the two layers. The two layers may include polymer resin and the barrier layer may include an inorganic material (e.g., silicon oxide, silicon nitride, silicon oxynitride, and/or the like).

First to third light-emitting devices ED1, ED2, and ED3, a light-receiving device PD, a pixel circuit PC, and a sensor circuit PC′ may be arranged on the substrate 100. The pixel circuit PC may be electrically connected to the light-emitting device ED, and the sensor circuit PC′ may be electrically connected to the light-receiving device PD.

Light emission of the first light-emitting device ED1, the second light-emitting device ED2, and the third light-emitting device ED3 may be controlled or selected by electrical connection of the first light-emitting device ED1, the second light-emitting device ED2, and the third light-emitting device ED3 to the pixel circuit PC. In one or more embodiments, light detection may be controlled or selected by electrically connecting the first light-receiving device PD1 to the sensor circuit PC′. The pixel circuit PC may include a plurality of thin-film transistors TFT and a storage capacitor Cst and may be substantially the same as the structure of the pixel circuit PC described with reference to FIG. 3. For convenience of illustration, one thin-film transistor TFT is illustrated in FIG. 5, and the thin-film transistor TFT may correspond to the first transistor (see T1 of FIG. 3) described above. Likewise, the sensor circuit PC′ may include a plurality of thin-film transistors TFT′ and may be substantially the same as the structure of the sensor circuit PC′ described with reference to FIG. 3. For convenience of illustration, one thin-film transistor TFT′ is illustrated in FIG. 5, and the thin-film transistor TFT′ may correspond to the eighth transistor (see T8 of FIG. 3) described above. For convenience of explanation, the following description is given focusing on one pixel circuit PC.

A buffer layer 201 including an inorganic material, such as silicon oxide, silicon nitride, and/or silicon oxynitride, may be between the thin-film transistor TFT and the substrate 100. The buffer layer 201 may increase the smoothness of the upper surface of the substrate 100, or may prevent or reduce or minimize or reduce infiltration of impurities from the substrate 100 and/or the like to a semiconductor layer Act of the thin-film transistor TFT.

As illustrated in FIG. 5, the thin-film transistor TFT may include the semiconductor layer Act including amorphous silicon, polycrystalline silicon, an organic semiconductor material, or an oxide semiconductor material. The thin-film transistor TFT may include a gate electrode GE, a source electrode SE, and/or a drain electrode DE. The gate electrode GE may include one or more suitable conductive materials (e.g., conductors) and have one or more suitable layered structures. For example, the gate electrode GE may include a Mo layer and an Al layer. In one or more embodiments, the gate electrode GE may include a TiNX layer, an Al layer, and/or a Ti layer. The source electrode SE and the drain electrode DE may also include one or more suitable conductive materials and have one or more suitable layered structures. For example, each of the source electrode SE and the drain electrode DE may include a Ti layer, an Al layer, and/or a Cu layer.

In order to secure electrical insulating properties between the semiconductor layer Act and the gate electrode GE, a gate insulating layer 203 including an inorganic material, such as silicon oxide, silicon nitride, and/or silicon oxynitride, may be between the semiconductor layer Act and the gate electrode GE. Although FIG. 5 illustrates that the gate insulating layer 203 has a shape corresponding to the entire surface of the substrate 100 and has a structure in which contact holes are formed in preset portions, the disclosure is not limited thereto. For example, the gate insulating layer 203 may be patterned to have the same shape as the gate electrode GE.

In one or more embodiments, a first interlayer insulating layer 205 including an inorganic material, such as silicon oxide, silicon nitride, and/or silicon oxynitride, may be arranged on the gate electrode GE. The first interlayer insulating layer 205 may have a single-layer or multilayer structure including the material described above. The insulating layer including the inorganic material described above, such as the gate insulating layer 203 and/or the interlayer insulating layer 205, may be formed by chemical vapor deposition (CVD) and/or atomic layer deposition (ALD).

The storage capacitor Cst may include a first electrode CE1 and a second electrode CE2 that overlap each other with the first interlayer insulating layer 205 therebetween in a z-axis direction. The storage capacitor Cst may overlap the thin-film transistor TFT in the z-axis direction. In this regard, FIG. 5 illustrates that the gate electrode GE of the thin-film transistor TFT is the first electrode CE1 of the storage capacitor Cst, but the disclosure is not limited thereto. For example, the storage capacitor Cst may not overlap the thin-film transistor TFT. The second electrode CE2 of the storage capacitor Cst may include a conductive material including molybdenum (Mo), aluminum (Al), copper (Cu), titanium (Ti), and/or the like and may include a single layer or layers including the conductive material described above.

A second interlayer insulating layer 207 including an inorganic material, such as silicon oxide, silicon nitride, and/or silicon oxynitride, may be arranged on the second electrode CE2 of the storage capacitor Cst. The second interlayer insulating layer 207 may have a single-layer or multilayer structure including the inorganic material described above.

The source electrode SE and the drain electrode DE may be arranged on the second interlayer insulating layer 207. A data line DL may be arranged on the same layer as the source electrode SE and the drain electrode DE (may be arranged on) and may include the same material as the source electrode SE and the drain electrode DE. The source electrode SE, the drain electrode DE, and the data line DL may each include a material excellent or suitable conductivity. The source electrode SE and the drain electrode DE may each include a conductive material including molybdenum (Mo), aluminum (Al), copper (Cu), titanium (Ti), and/or the like and may include a single-layer or multilayer structure including the conductive material described above. For example, the source electrode SE, the drain electrode DE, and the data line DL may each have a multilayer structure of Ti/Al/Ti. The disclosure is not limited thereto. For example, the thin-film transistor TFT may have only one of (selected from among) the source electrode SE and/or the drain electrode DE, or may not have both (e.g., simultaneously) of the source electrode SE and the drain electrode DE.

A planarization layer 208 may be arranged to cover the thin-film transistor TFT and the storage capacitor Cst. The planarization layer 208 may include an organic insulating material. For example, the planarization layer 208 may include photoresist, benzocyclobutene (BCB), polyimide, hexamethyldisiloxane (HMDSO), polymethylmethacrylate (PMMA), polystyrene, polymer derivatives having a phenolic group, acrylic polymer, imide-based polymer, aryl ether-based polymer, amide-based polymer, fluorine-based polymer, p-xylene-based polymer, vinyl alcohol-based polymer, or any mixture thereof. In some embodiments, a third interlayer insulating layer may be further arranged below the planarization layer 208. The third interlayer insulating layer may include an inorganic insulating material, such as silicon oxide, silicon nitride, or silicon oxynitride.

The first light-emitting device ED1, the second light-emitting device ED2, the third light-emitting device ED3, and the first light-receiving device PD1 may be spaced apart from each other on the planarization layer 208. The first light-emitting device ED1, the second light-emitting device ED2, and the third light-emitting device ED3 may be configured to externally emit pieces of light of different colors. For example, the first light-emitting device ED1 may be configured to externally emit green light, the second light-emitting device ED2 may be configured to externally emit red light, and the third light-emitting device ED3 may be configured to externally emit blue light. The first light-receiving device PD1 may be configured to detect light emitted from the first to third light-emitting devices ED1, ED2, and ED3 and light reflected from an object.

The first light-emitting device ED1 may include a first pixel electrode 210-1, a first intermediate layer 220-1, and an opposite electrode 230. The second light-emitting device ED2 may include a second pixel electrode 210-2, a second intermediate layer 220-2, and an opposite electrode 230. The third light-emitting device ED3 may include a third pixel electrode 210-3, a third intermediate layer 220-3, and an opposite electrode 230. The first light-receiving device PD1 may include a first sensing electrode 210-4, a fourth intermediate layer 220-4, and an opposite electrode 230. For example, the first pixel electrode 210-1, the second pixel electrode 210-2, the third pixel electrode 210-3, and the first sensing electrode 210-4, which are respectively provided in the first light-emitting device ED1, the second light-emitting device ED2, the third light-emitting device ED3, and the first light-receiving device PD1, may be patterned for each pixel. The opposite electrodes 230 of the first light-emitting device ED1, the second light-emitting device ED2, the third light-emitting device ED3, and the first light-receiving device PD1 may be integrally formed as a single body over the first light-emitting device ED1, the second light-emitting device ED2, the third light-emitting device ED3, and the first light-receiving device PD1. A first intermediate layer 220-1, a second intermediate layer 220-2, a third intermediate layer 220-3, and a fourth intermediate layer 220-4 may be respectively between the opposite electrode 230 and the first pixel electrode 210-1, the second pixel electrode 210-2, the third pixel electrode 210-3, and the first sensing electrode 210-4.

The first pixel electrode 210-1, the second pixel electrode 210-2, the third pixel electrode 210-3, and the first sensing electrode 210-4 may be apart from each other and arranged on the substrate 100. The first pixel electrode 210-1, the second pixel electrode 210-2, the third pixel electrode 210-3, and the first sensing electrode 210-4 may include a transmissive conductive layer including a transmissive conductive oxide, such as indium tin oxide (ITO), In₂O₃, or indium zinc oxide (IZO), and a reflective layer including metal, such as Al or Ag. For example, the first pixel electrode 210-1, the second pixel electrode 210-2, the third pixel electrode 210-3, and the first sensing electrode 210-4 may each have a three-layer structure of ITO/Ag/ITO.

The first pixel electrode 210-1, the second pixel electrode 210-2, and the third pixel electrode 210-3 may each be in contact with one of the source electrode SE and the drain electrode DE and thus electrically connected to the thin-film transistor TFT, as illustrated in FIG. 5. For example, each of the first pixel electrode 210-1, the second pixel electrode 210-2, and the third pixel electrode 210-3 may be in contact with one of the source electrode SE and the drain electrode DE through a contact hole formed in the planarization layer 208. Likewise, the first sensing electrode 210-4 may be electrically connected to the thin-film transistor TFT′ through a contact hole formed in the planarization layer 208.

A bank layer 215 may be arranged on the planarization layer 208. Because the bank layer 215 has openings corresponding to the first to third light-emitting devices ED1, ED2, and ED3) and the first light-receiving device PD1, that is, an opening exposing at least the central portion of the pixel electrode (or the sensing electrode), the bank layer 215 may serve to define the emission area EA and the sensing area SA. For example, the bank layer 215 may have a plurality of openings, for example, first to fourth openings (see OP1, OP2, OP3, and OP4 of FIG. 4) respectively exposing the central portions of the first pixel electrode 210-1, the second pixel electrode 210-2, the third pixel electrode 210-3, and the first sensing electrode 210-4. In one or more embodiments, the bank layer 215 may increase the distance between the pixel electrode and the opposite electrode 230 or the distance between the sensing electrode and the opposite electrode 230. Due to this, an electric arc and/or the like may be prevented or reduced from occurring at the edges of the first to third pixel electrodes 210-1, 210-2, and 210-3 and/or at the edges of the first sensing electrode 210-4. The bank layer 215 may include, for example, an organic material, such as polyimide and/or hexamethyldisiloxane (HMDSO).

The opposite electrode 230 may be arranged on the first pixel electrode 210-1. The opposite electrode 230 may be integrally formed as a single body over the first light-emitting device ED1, the second light-emitting device ED2, the third light-emitting device ED3, and the first light-receiving device PD1. Accordingly, the opposite electrode 230 may also be arranged on the second pixel electrode 210-2, the third pixel electrode 210-3, and the first sensing electrode 210-4. The opposite electrode 230 may include a transmissive conductive layer including ITO, In₂O₃, or IZO, and may also include a semi-transmissive layer including metal, such as Al or Ag. For example, the opposite electrode 230 may be a semi-transmissive layer including Mg or Ag.

The first intermediate layer 220-1 may be between the first pixel electrode 210-1 and the opposite electrode 230. The second intermediate layer 220-2 may be between the second pixel electrode 210-2 and the opposite electrode 230, and the third intermediate layer 220-3 may be between the third pixel electrode 210-3 and the opposite electrode 230. The fourth intermediate layer 220-4 may be between the first sensing electrode 210-4 and the opposite electrode 230. For example, the first intermediate layer 220-1 may be arranged on the first pixel electrode 210-1, and the second intermediate layer 220-2 may be arranged on the second pixel electrode 210-2. The third intermediate layer 220-3 may be arranged on the third pixel electrode 210-3, and the fourth intermediate layer 220-4 may be arranged on the first sensing electrode 210-4.

As illustrated in FIG. 6, each of the first light-emitting device ED1, the second light-emitting device ED2, and the third light-emitting device ED3 may be provided in a tandem structure including a plurality of emission layers. Because each of the first light-emitting device ED1, the second light-emitting device ED2, and the third light-emitting device ED3 has a structure in which a plurality of emission layers are stacked, color purity and light emission efficiency may be improved. In one or more embodiments, similar to the tandem structure of each of the first to third light-emitting devices ED1, ED2, and ED3, the first light-receiving device PD1 may have a double stack structure in which active layers and/or the like are stacked.

In one or more embodiments, each of the first intermediate layer 220-1, the second intermediate layer 220-2, and the third intermediate layer 220-3 respectively included in the first to third light-emitting devices ED1, ED2, and ED3 may include a plurality of emission layers. For example, the first intermediate layer 220-1 may include a first lower emission layer 223b-1 and a first upper emission layer 227b-1. The first lower emission layer 223b-1 may be arranged on the first pixel electrode 210-1, and the first upper emission layer 227b-1 may be arranged on the first lower emission layer 223b-1 so as to overlap the first lower emission layer 223b-1. Likewise, the second intermediate layer 220-2 may include a second lower emission layer 223b-2 and a second upper emission layer 227b-2 arranged on the second lower emission layer 223b-2, and the third intermediate layer 220-3 may include a third lower emission layer 223b-3 and a third upper emission layer 227b-3 arranged on the third lower emission layer 223b-3.

In one or more embodiments, the fourth intermediate layer 220-4 included in the first light-receiving device PD1 may have a double stack structure including an active layer and/or the like. In one or more embodiments, the fourth intermediate layer 220-4 may include an active layer 223b-4 and a sub-charge generation layer SCGL. As illustrated in FIGS. 5 and 6, the sub-charge generation layer SCGL may overlap the active layer 223b-4 and may be arranged on the active layer 223b-4. The active layer 223b-4 may be arranged on substantially the same layer as the first to third lower emission layers 223b-1, 223b-2, and 223b-3 (may be arranged on), and the sub-charge generation layer SCGL may be arranged on substantially the same layer as the first to third upper emission layers 227b-1, 227b-2, and 227b-3 (may be arrange on).

The first lower emission layer 223b-1, the second lower emission layer 223b-2, the third lower emission layer 223b-3, and the active layer 223b-4 may be provided individually by being patterned for the first light-emitting device ED1, the second light-emitting device ED2, the third light-emitting device ED3, and the first light-receiving device PD1. In one or more embodiments, the first upper emission layer 227b-1, the second upper emission layer 227b-2, the third upper emission layer 227b-3, and the sub-charge generation layer SCGL may be provided individually by being patterned for the first light-emitting device ED1, the second light-emitting device ED2, the third light-emitting device ED3, and the first light-receiving device PD1.

The first light-emitting device ED1 may be configured to externally emit green light, the second light-emitting device ED2 may be configured to externally emit red light, and the third light-emitting device ED3 may be configured to externally emit blue light. In order to implement such light emission, the first lower emission layer 223b-1 and the first upper emission layer 227b-1 may be configured to externally emit green light, the second lower emission layer 223b-2 and the second upper emission layer 227b-2 may be configured to externally emit red light, and the third lower emission layer 223b-3 and the third upper emission layer 227b-3 may be configured to externally emit blue light. The first lower emission layer 223b-1, the second lower emission layer 223b-2, and the third lower emission layer 223b-3 may constitute a first unit UN1, and the first upper emission layer 227b-1, the second upper emission layer 227b-2, and the third upper emission layer 227b-3 may constitute a second unit UN2.

The first to third lower emission layers 223b-1, 223b-2, and 223b-3 and the first to third upper emission layers 227b-1, 227b-2, and 227b-3 may each include an organic material including a fluorescent or phosphorescent material that are configured to emit red light, green light, or blue light. The first to third lower emission layers 223b-1, 223b-2, and 223b-3 and the first to third upper emission layers 227b-1, 227b-2, and 227b-3 may each be an organic emission layer including a relatively low molecular weight organic material or a relatively high molecular weight organic material. The first to third lower emission layers 223b-1, 223b-2, and 223b-3 and the first to third upper emission layers 227b-1, 227b-2, and 227b-3 may each be an organic emission layer including copper phthalocyanine, tris-8-hydroxyquinoline aluminum, a poly-phenylenevinylene (PPV)-based material, and/or a polyfluorene-based material.

In one of more embodiments, the first to third lower emission layers 223b-1, 223b-2, and 223b-3 and the first to third upper emission layers 227b-1, 227b-2, and 227b-3 may each include a host material and a dopant material. The dopant material is a material that is configured to emit light of a specific color and may include a light-emitting material. The light-emitting material may include at least one of a phosphorescent dopant, a fluorescent dopant, or a quantum dot. The host material is a main material of the emission layer and is a material that helps the dopant material emit light.

The first light-receiving device PD1 may be configured to detect light emitted from the first light-emitting device ED1, the second light-emitting device ED2, and the third light-emitting device ED3 and light reflected from an object aspect. The first light-receiving device PD1 may be configured to detect light reflected from an object as the active layer 223b-4 absorbs light and converts the absorbed light into an electrical signal. For example, the active layer 223b-4 is a layer configured to receive light from the outside, generate excitons, and then separate the generated excitons into holes and electrons.

In one or more embodiments, the active layer 223b-4 may be arranged in a lower stack in the double stack structure of the first light-receiving device PD1. For example, the active layer 223b-4 may be arranged on substantially the same layer as the first to third lower emission layers 223b-1, 223b-2, and 223b-3 (may be arranged on and as) described above to constitute the first unit UN1. In one or more embodiments, the active layer 223b-4 may be configured to detect green light emitted from the first light-emitting device ED1 and light reflected from the object. For example, the active layer 223b-4 may be configured to absorb light of about 495 nm to about 570 nm corresponding to green light. However, the disclosure is not limited thereto, and the active layer 223b-4 may be configured to detect light emitted from the second light-emitting device ED2 and the third light-emitting device ED3 according to the material included therein. In some cases, the active layer 223b-4 may be configured to detect light in a near-infrared band.

The active layer 223b-4 may include a p-type or kind (e.g., p) semiconductor compound and an n-type or kind (e.g., n) semiconductor compound. For example, the active layer 223b-4 may be a mixed layer including a p-type or kind semiconductor compound and an n-type or kind semiconductor compound. In one or more embodiments, the active layer 223b-4 may have a structure in which a layer including a p-type or kind semiconductor compound and a layer including an n-type or kind semiconductor compound are stacked. The layer including the p-type or kind semiconductor compound and the layer including the n-type or kind semiconductor compound may form (or provide) a PN junction. Excitons may be efficiently separated into holes and electrons by photoinduced charge separation that occurs at the interface of these layers.

The p-type or kind semiconductor compound included in the active layer 223b-4 may be a compound that acts as an electron donor to donate electrons. For example, the p-type or kind semiconductor compound may be an organic compound capable of donating electrons. For example, the p-type or kind semiconductor compound may include or be a triarylamine compound, a benzidine compound, a pyrazoline compound, a styrylamine compound, a hydrazone compound, a triphenyl methane compound, a carbazole compound, a polysilane compound, a thiophene compound, a phthalocyanine compound, a naphthalocyanine compound, a cyanine compound, a melocyanine compound, an oxonol compound, a polyamine compound, an indole compound, a pyrrole compound, a pyrazole compound, a polyarylene compound, a condensed aromatic carbon ring compound (naphthalene derivatives, anthracene derivatives, phenanthrene derivatives, tetracene derivatives, pyrene derivatives, perylene derivatives, fluoranthene derivatives, and/or the like), and/or a metal complex having a nitrogen-containing heterocyclic compound as a ligand, but the disclosure is not limited thereto.

In one or more embodiments, the p-type or kind semiconductor compound may include or be a compound represented by Formula 1:

### Formula 1

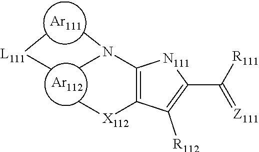

In Formula 1, Ar₁₁₁ and Ar₁₁₂ may each independently be a C₆-C₃₀ arylene group unsubstituted or substituted with at least one R₁₀ₐ or a C₃-C₃₀ heteroarylene group unsubstituted or substituted with at least one R₁₀ₐ. X₁₁₁ may be (e.g., selected from among) —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and/or —Ge(Q₁₁₁)(Q₁₁₂)-, and X₁₁₂ and L₁₁₁ may each be (e.g., selected from among) —O—, —S—, —Se—, —Te—, —S(═O)—, —S(═O)₂—, —N(Q₁₁₁)-, —B(Q₁₁₁)-, —C(Q₁₁₁)(Q₁₁₂)—, —Si(Q₁₁₁)(Q₁₁₂)-, —Ge(Q₁₁₁)(Q₁₁₂)-, —(C(Q₁₁₁)=C(Q₁₁₂))-, and/or —(C(Q₁₁₁)=N)—. When L₁₁₁ is (e.g., selected from among) —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and/or —(C(Q₁₁₁)=N)—, L₁₁₁ may be optionally connected to Ar₁₁₁ or Ar₁₁₂ to form (or provide) a condensed ring, and Z₁₁₁ may be a C₆-C₃₀ carbocyclic group having at least one functional group of (e.g., selected from among) C═O, C═S, C═Se, and/or C═Te and unsubstituted or substituted with at least one R₁₀ₐ or a C₁-C₃₀ heterocyclic group having at least one functional group of (e.g., selected from among) C═O, C═S, C═Se, and/or C═Te and substituted or unsubstituted with at least one R₁₀ₐ.

R₁₁₁ to R₁₁₆ may each independently be hydrogen, deuterium, a halogen, a cyano group, a nitro group, a hydroxyl group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, a C₂-C₃₀ acyl group unsubstituted or substituted with at least one R₁₀ₐ, or a (e.g., any suitable) combination thereof.

R₁₀ₐ may be (e.g., selected from among): deuterium (-D), —F, —Cl, —Br, —I, a hydroxyl group, a cyano group, a nitro group, or a (e.g., any suitable) combination thereof; and a C₁-C₆₀ alkyl group, a C₂-C₆₀ alkenyl group, a C₂-C₆₀ alkynyl group, and/or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a (e.g., any suitable) combination thereof. In one or more embodiments, R₁₀ₐ may be a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof, or may be —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof.

Q₁₁ to Q₁₃, Q₂₁ to Q₂₃, Q₃₁, Q₃₂, Q₁₁₁, and Q₁₁₂ may each independently be (e.g., selected from among): hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or a (e.g., any suitable) combination thereof.

In one or more embodiments, Z₁₁₁ of Formula 1 may be represented by one of (e.g., selected from among) Formulae 111A to 111F:

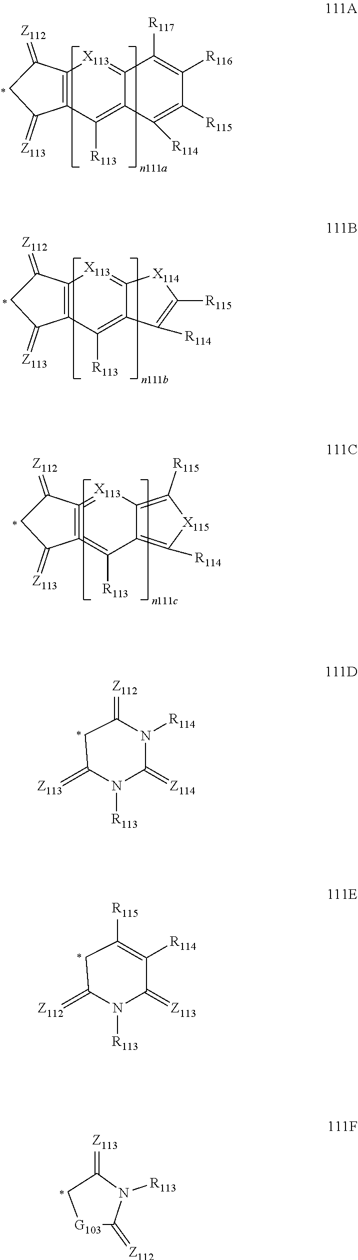

In Formulae 111A to 111F, Z₁₁₂ to Z₁₁₄ may each be O, S, Se, or Te, X₁₁₃ may be N or C(Q₁₁₃), and X₁₁₄ and X₁₁₅ may each independently be O, S, Se, Te, Si(Q₁₁₁)(Q₁₁₂), or Ge(Q₁₁₁)(Q₁₁₂). n₁₁₁ₐ to n_{111c} may each be an integer from 0 to 3. R₁₁₃ to R₁₁₇ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof. The definitions of Q₁₁₁ to Q₁₁₃ may be the same as the definition of Q₁₁₁ described above.

The n-type or kind semiconductor compound included in the active layer 223b-4 may be a compound that acts as an electron acceptor to accept electrons. For example, the n-type or kind semiconductor compound may be an organic compound capable of accepting electrons. For example, the n-type or kind semiconductor compound may be fullerene, fullerene derivative, a condensed aromatic carbon ring compound (naphthalene derivatives, anthracene derivatives, phenanthrene derivatives, tetracene derivatives, pyrene derivatives, perylene derivatives, fluoranthene derivatives, and/or the like), a 5- to 7-membered heterocyclic compound containing a nitrogen atom, an oxygen atom, and a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazole, pyridazine, triazolopyrimidine, tetrazynedene, oxadiazole, imidazopyridine, pyrrolidine, pyrrolopyridine, thiadiazolopyridine, dibenzepine, tribenzazepine, and/or the like), a polyarylene compound, a fluorene compound, a cyclopentadiene compound, a silyl compound, or a metal complex having a nitrogen-containing heterocyclic compound as a ligand, but the disclosure is not limited thereto.

In one or more embodiments, the n-type or kind semiconductor compound may include or be a compound represented by (e.g., selected from among) Formula 2 or 3:

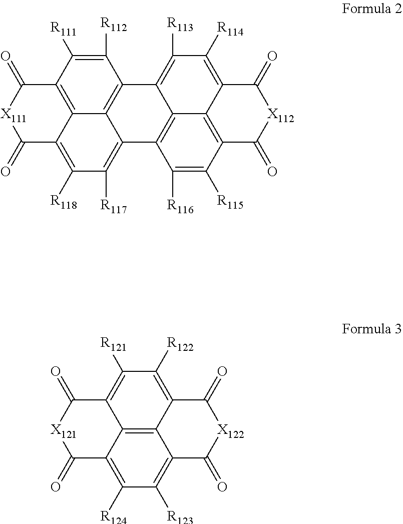

In Formula 2, X₁₁₁ and X₁₁₂ may each independently be O or NR₁₁₉, and R₁₁₁ to R₁₁₉ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof.

In Formula 3, X₁₂₁ and X₁₂₂ may each independently be O or NR₁₂₅, and R₁₂₁ to R₁₂₅ may each independently be hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof.

In Formulae 2 and 3, R₁₀ₐ may be (e.g., selected from among): deuterium (-D), —F, —Cl, —Br, —I, a hydroxyl group, a cyano group, or a nitro group; and a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), and/or a (e.g., any suitable) combination thereof.

In one or more embodiments, R₁₀ₐ may be a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a (e.g., any suitable) combination thereof, or may be —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a (e.g., any suitable) combination thereof.

Q₁₁ to Q₁₃, Q₂₁ to Q₂₃, Q₃₁, and Q₃₂ may each independently be (e.g., selected from among): hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, and/or a (e.g., any suitable) combination thereof.

In one or more embodiments, the n-type or kind semiconductor compound may include or be one of (e.g., selected from among) the following compounds.

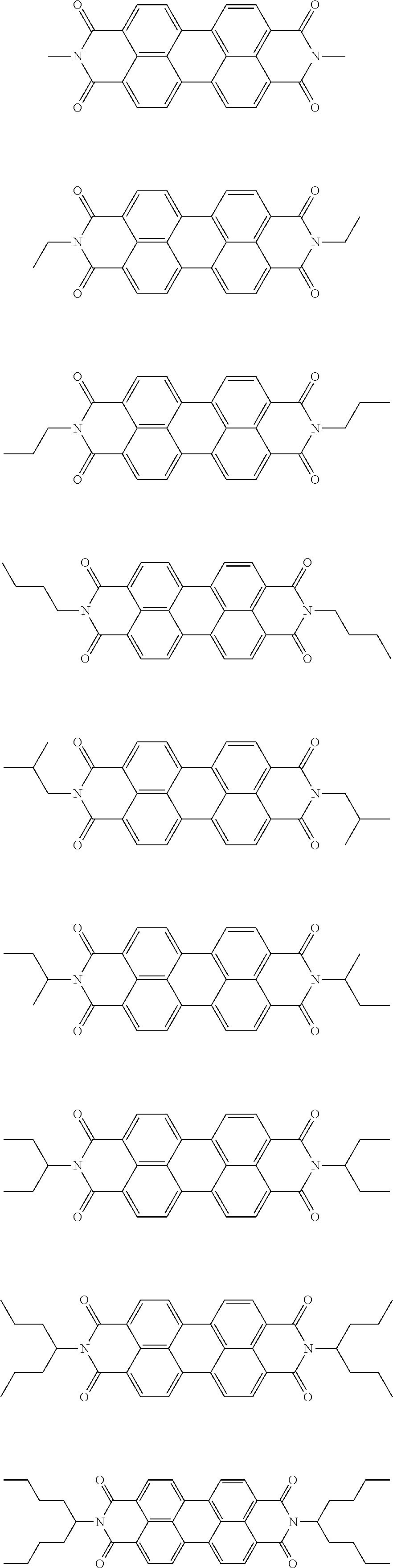

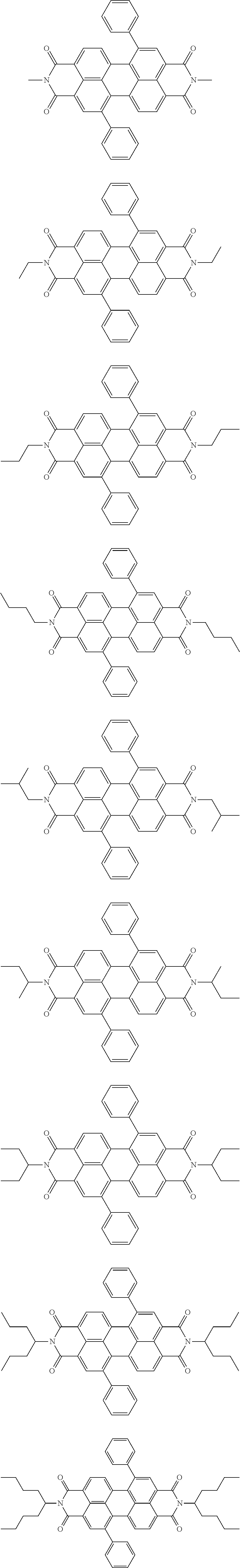

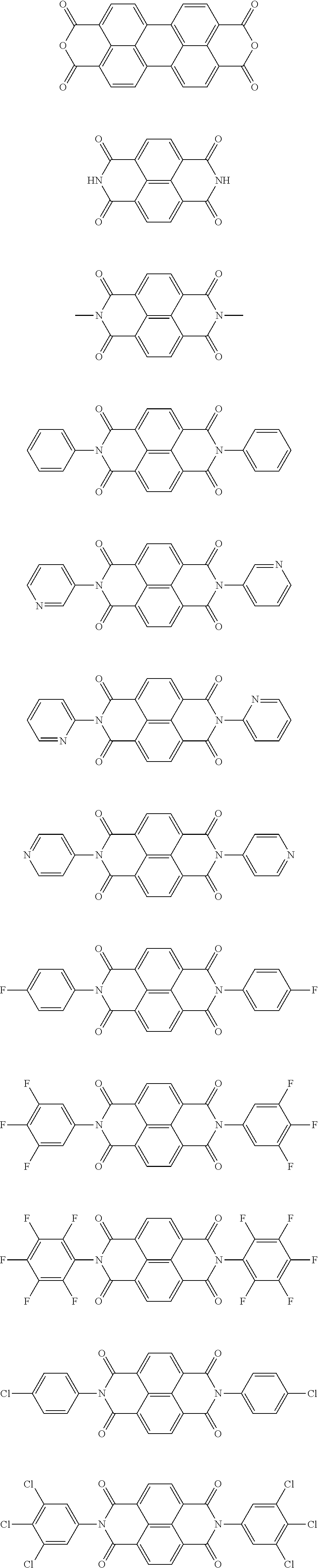

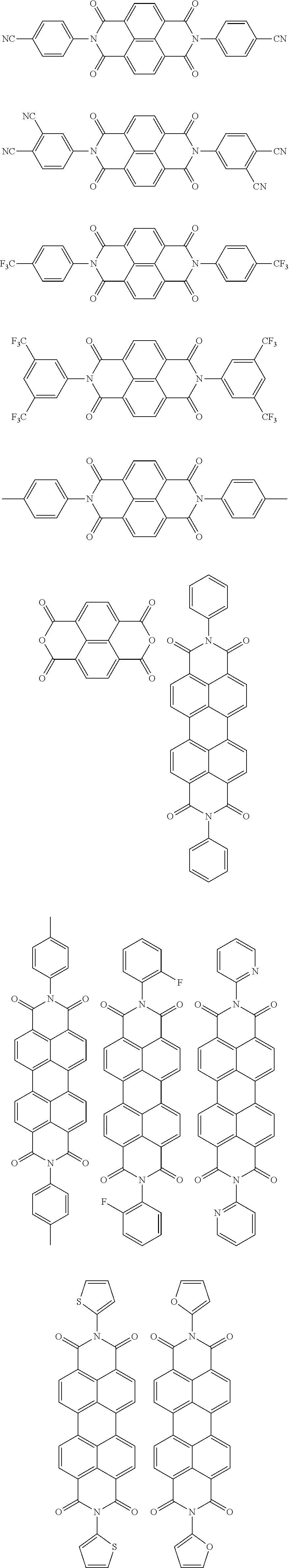

In contrast, the first light-receiving device PD1 may further include a sub-charge generation layer SCGL arranged in the upper stack of the double stack structure. For example, the sub-charge generation layer SCGL may be arranged on substantially the same layer as the first to third upper emission layers 227b-1, 227b-2, and 227b-3 (may be arranged on and as) described above to constitute a second unit UN2. The sub-charge generation layer SCGL may serve to supply charges to the double stack structure of the first light-receiving device PD1 including the first unit UN1 and the second unit UN2.

In other words, the first light-receiving device PD1 may have the double stack structure of the active layer 223b-4 arranged in the lower stack and the sub-charge generation layer SCGL arranged in the upper stack. As illustrated in FIG. 5, when the first light-receiving device PD1 has a structure in which the active layer 223b-4 and the sub-charge generation layer SCGL are stacked, device efficiency may be superior, compared to the case where the first light-receiving device PD1 has a structure in which two active layers are stacked. For example, when the active layer is arranged in the lower stack and the active layer is also arranged in the upper stack, the active layer arranged in the upper stack may be configured to absorb most of the light reflected from the object, and thus, a small amount of light may reach the active layer arranged in the lower stack. In this case, because the active layer arranged in the lower stack may not operate properly, the overall current flow of the first light-receiving device PD1 may not be smooth. In contrast, when the first light-receiving device PD1 includes a structure in which the active layer 223b-4 and the sub-charge generation layer SCGL are stacked, the sub-charge generation layer SCGL may serve to supply charges and a sufficient amount of light may reach the active layer 223b-4 arranged in the lower stack. Therefore, device efficiency may be improved.

For example, the sub-charge generation layer SCGL may include a p-type or kind sub-charge generation layer 227p and an n-type or kind (e.g., n sub-charge) sub-charge generation layer 227n arranged on the p-type or kind (e.g., p sub-charge) sub-charge generation layer 227p. The p-type or kind sub-charge generation layer 227p may supply holes to the lower portion of the sub-charge generation layer SCGL, and the n-type or kind sub-charge generation layer 227n may supply electrons to the upper portion of the sub-charge generation layer SCGL. The n-type or kind sub-charge generation layer 227n may be arranged on the p-type or kind sub-charge generation layer 227p and may be in contact with the p-type or kind sub-charge generation layer 227p. Because the first light-receiving device PD1 includes the sub-charge generation layer SCGL as described above, the flow of current in the first light-receiving device PD1 may become smooth and light-receiving efficiency may be increased.

The n-type or kind sub-charge generation layer 227n may include an n-type or kind dopant material and an n-type or kind host material. The n-type or kind dopant material may be metals of Groups 1 and 2 in the periodic table of the elements, an organic material capable of injecting electrons, or any mixture thereof. For example, the n-type or kind dopant material may be one of an alkali metal and an alkaline earth metal. In other words, the n-type or kind sub-charge generation layer 227n may include an inorganic layer doped with an alkali metal, such as lithium (Li), sodium (Na), potassium (K), or cesium (Cs), or an alkaline earth metal, such as magnesium (Mg), strontium (Sr), barium (Ba), or radium (Ra), but the disclosure is not limited thereto. The n-type or kind host material may include one of the materials capable of transferring electrons, for example, tris(8-hydroxyquinolino)aluminum (Alq3), 8-hydroxyquinolinolato-lithium (Liq), 2-(4-biphenylyl)-5-(4-tert-butylphenyl)-1,3,4oxadiazole (PBD), 3-(4-biphenyl)4-phenyl-5-tert-butylphenyl-1,2,4-triazole (TAZ), spiro-PBD, bis(2-methyl-8-quinolinolate)-4-(phenylphenolato)aluminium (BAlq), SAlq, 2,2′,2-(1,3,5-benzinetriyl)-tris(1-phenyl-1-H-benzimidazole (TPBi), oxadiazole, triazole, phenanthroline, benzoxazole, and benzthiazole, and the disclosure is not limited thereto.

The p-type or kind sub-charge generation layer 227p may include a p-type or kind dopant material and a p-type or kind host material. The p-type or kind dopant material may include a metal oxide, an organic material, such as tetrafluoro-tetracyanoquinodimethane (F4-TCNQ), hexaazatriphenylene-hexacarbonitrile (HAT-CN), or hexaazatriphenylene, or a metal material, such as V₂O₅, MoOₓ, or WO₃, but the disclosure is not limited thereto. The p-type or kind host material may include a material including at least one of materials capable of transferring holes, for example, N,N-dinaphthyl-N,N′-diphenyl benzidine (NPD), N,N′-bis(naphthalene-1-yl)-N,N′-bis(phenyl)-2,2′-dimethylbenzidine, N,N′-bis-(3-methylphenyl)-N,N′-bis-(phenyl)-benzidine (TPD), and 4,4′,4-tris(N-3-methylphenyl-N-phenyl-amino)-triphenylamine (MTDATA), but the disclosure is not limited thereto.

Referring again to FIGS. 5 and 6, a main charge generation layer MCGL may be between the first unit UN1 and the second unit UN2. For example, the main charge generation layer MCGL may be between the first lower emission layer 223b-1 and the first upper emission layer 227b-1, between the second lower emission layer 223b-2 and the second upper emission layer 227b-2, between the third lower emission layer 223b-3 and the third upper emission layer 227b-3, and between the active layer 223b-4 and the sub-charge generation layer SCGL.

The main charge generation layer MCGL may include an n-type or kind main charge generation layer 224 and a p-type or kind main charge generation layer 225 arranged on the n-type or kind main charge generation layer 224. The p-type or kind main charge generation layer 225 may be arranged on the n-type or kind main charge generation layer 224 and may be in contact with the n-type or kind main charge generation layer 224. The n-type or kind main charge generation layer 224 may include the same material as the n-type or kind sub-charge generation layer 227n, and the p-type or kind main charge generation layer 225 may include the same material as the p-type or kind sub-charge generation layer 227p. However, the disclosure is not limited thereto, and the main charge generation layer MCGL and the sub-charge generation layer SCGL may include different materials.

The n-type or kind main charge generation layer 224 may be integrally formed as a single body over the first to third light-emitting devices ED1, ED2, and ED3 and the first light-receiving device PD1. In contrast, the p-type or kind main charge generation layer 225 may be patterned for each light-emitting device and each light-receiving device. For example, the p-type or kind main charge generation layer 225 may include a first p-type or kind main charge generation layer 225-1 arranged on the first light-emitting device ED1, a second p-type or kind main charge generation layer 225-2 arranged on the second light-emitting device ED2, a third p-type or kind main charge generation layer 225-3 arranged on the third light-emitting device ED3, and a fourth p-type or kind main charge generation layer 225-4 arranged on the first light-receiving device PD1. The first to fourth type or kind main charge generation layers 225-1, 225-2, 225-3, and 225-4 may have different thicknesses so as to compensate for the resonance distance of the light-emitting devices or light-receiving devices individually formed and arranged. However, the disclosure is not limited thereto, and the p-type or kind main charge generation layer 225 may be integrally formed as a single body like the n-type or kind main charge generation layer 224.

The main charge generation layer MCGL having the above-described structure may serve to generate charges in the first to third light-emitting devices ED1, ED2, and ED3. For example, the n-type or kind main charge generation layer 224 may be configured to supply electrons to the first unit UN1, and the p-type or kind main charge generation layer 225 may be configured to supply holes to the second unit UN2. For example, the main charge generation layer MCGL arranged in the first to third light-emitting devices ED1, ED2, and ED3 may serve to supply charges to the tandem structure like the sub-charge generation layer SCGL. Because the main charge generation layer MCGL is between the first to third lower emission layers 223b-1, 223b-3, and 223b-3 and the first to third upper emission layers 227b-1, 227b-2, and 227b-3, the flow of the current in the units of each of the first to third light-emitting devices ED1, ED2, and ED3 becomes smooth, and thus, the respective units may be driven normally.

In contrast, the main charge generation layer MCGL arranged on the first light-receiving device PD1 may serve to promote the recombination of holes and electrons. As described above, because the sub-charge generation layer SCGL included in the upper stack of the first light-receiving device PD1 already serves to generate charges, the main charge generation layer MCGL arranged in the first light-receiving device PD1 may not generate charges unlike the main charge generation layer MCGL arranged in the first to third light-emitting devices ED1, ED2, and ED3. Instead, the main charge generation layer MCGL arranged in the first light-receiving device PD1 may be a point where electrons generated in the active layer 223b-4 meet holes generated in the sub-charge generation layer SCGL. Accordingly, the electrons of the active layer 223b-4 and the holes of the sub-charge generation layer SCGL are recombined in the main charge generation layer MCGL, and thus, material deterioration may be prevented or reduced and the flow of the current in the first light-receiving device PD1 may be made smooth. As a result, because the first light-receiving device PD1 included in the display apparatus 1 according to one or more embodiments includes the dual charge generation layer structure of the main charge generation layer MCGL and the sub-charge generation layer SCGL, sensing sensitivity and device efficiency of the first light-receiving device PD1 may be improved.

In contrast, the first unit UN1 may further include a first common layer 221 and a second common layer 222. The first common layer 221 and the second common layer 222 may be between the first pixel electrode 210-1 and the first lower emission layer 223b-1, between the second pixel electrode 210-2 and the second lower emission layer 223b-2, between the third pixel electrode 210-3 and the third lower emission layer 223b-3, and between the first sensing electrode 210-4 and the active layer 223b-4. The first common layer 221 and the second common layer 222 may be integrally formed as a single body over the first to third light-emitting devices ED1, ED2, and ED3 and the first light-receiving device PD1.

The first common layer 221 and the second common layer 222 may constitute a hole transport region. The hole transport region may have a single-layer structure or a multilayer structure. For example, the first common layer 221 of the hole transport region may be a hole injection layer (HIL), and the second common layer 222 of the hole transport region may be a hole transport layer (HTL). In one or more embodiments, the hole transport region may further include an electron blocking layer (EBL).

The first common layer 221 and the second common layer 222 may each include at least one of (e.g., selected from among) m-MTDATA, TDATA, 2-TNATA, NPB (NPD), β-NPB, TPD, spiro-TPD, spiro-NPB, methylated-NPB, TAPC, HMTPD, 4,4′,4-tris(N-carbazolyl)triphenylamine (TCTA), polyaniline/dodecylbenzenesulfonic acid (PANI/DBSA), polyaniline/camphor sulfonic acid (PANI/CSA), poly(3,4-ethylenedioxythiophene)/poly(4-styrenesulfonate) (PEDOT/PSS), and/or polyaniline/poly(4-styrenesulfonate) (PANI/PSS).

In one or more embodiments, the first unit UN1 may further include an electron transport layer (ETL). The electron transport layer included in the first unit UN1 may be arranged below the n-type or kind main charge generation layer 224 and may include the same material as the n-type or kind main charge generation layer 224. However, the n-type or kind main charge generation layer 224 may be a layer doped with an n-type or kind dopant in the ETL.

In contrast, the second unit UN2 may further include a third common layer 226. The third common layer 226 may be an HTL and may transfer, to the second unit UN2, holes generated in the main charge generation layer MCGL. The third common layer 226 may include PEDOT or PANI.

The third common layer 226 may be between the main charge generation layer MCGL and the first to third upper emission layers 227b-1, 227b-2, and 227b-3 and between the main charge generation layer MCGL and the sub-charge generation layer SCGL. The third common layer 226 may be patterned for each light-emitting device and each light-receiving device. For example, the third common layer 226 may include a 3rd-1 common layer 226-1 arranged in the first light-emitting device ED1, a 3rd-2 common layer 226-2 arranged in the second light-emitting device ED2, a 3rd-3 common layer 226-3 arranged in the third light-emitting device ED3, and a 3rd-4 common layer 226-4 arranged in the first light-receiving device PD1. The 3rd-1 common layer 226-1, the 3rd-2 common layer 226-2, the 3rd-3 common layer 226-3, and the 3rd-4 common layer 226-4 may be formed to have different thicknesses so as to compensate for the resonance distance of the light-emitting devices or the light-receiving devices individually formed and arranged. However, the disclosure is not limited thereto, and the third common layer 226 may be integrally formed as a single body over the first to third light-emitting devices ED1, ED2, and ED3 and the first light-receiving device PD1.

In one or more embodiments, the second unit UN2 may further include a buffer layer 228 and a fourth common layer 229. The buffer layer 228 and the fourth common layer 229 may be between the first to third upper emission layers 227b-1, 227b-2, and 227b-3 and the opposite electrode 230 and between the sub-charge generation layer SCGL and the opposite electrode 230. The buffer layer 228 may include an inorganic material, such as silicon oxide, silicon nitride, and/or silicon oxynitride. The fourth common layer 229 may include an ETL and/or an electron injection layer (EIL). The fourth common layer 229 may include at least one compound of (e.g., selected from among) 2,9-dimethyl-4,7-diphenyl-1,10-phenanthroline (BCP), 4,7-diphenyl-1,10-phenanthroline (Bphen), Alq3, BAlq, TAZ, and/or NTAZ.

The display apparatus 1 may further include an auxiliary layer arranged below the emission layer and/or the active layer. The auxiliary layer may serve to increase device efficiency by compensating for the optical resonance distance according to the wavelength of light emitted from the emission layer and/or light incident on the active layer. For example, the thickness of the auxiliary layer may be about 100 angstrom (Å) to about 500 Å. Because the auxiliary layer is a layer added to adjust the resonance distance, the auxiliary layer may include a resonance auxiliary material. For example, the auxiliary layer may include the same material as the HTL.

The auxiliary layer may include a lower auxiliary layer 223a included in the first unit UN1 and an upper auxiliary layer 227a included in the second unit UN2. For example, the lower auxiliary layer 223a may be arranged the first to third lower emission layers 223b-1, 223b-2, and 223b-3 and the active layer 223b-4, and the upper auxiliary layer 227a may be arranged below the first to third upper emission layers 227b-1, 227b-2, and 227b-3.

The lower auxiliary layer 223a and the upper auxiliary layer 227a may be patterned for each light-emitting device and each light-receiving device. For example, the lower auxiliary layer 223a may include a first lower auxiliary layer 223a-1 arranged below the first lower emission layer 223b-1, a second lower auxiliary layer 223a-2 arranged below the second lower emission layer 223b-2, a third lower auxiliary layer 223a-3 arranged below the third lower emission layer 223b-3, and a fourth lower auxiliary layer 223a-4 arranged below the active layer 223b-4. The first to fourth lower auxiliary layers 223a-1, 223a-2, 223a-3, and 223a-4 may be formed individually and may be formed to have different thicknesses so as to compensate for the resonance distance of the light-emitting devices or the light-receiving devices. Similarly, the upper auxiliary layer 227a may include a first upper auxiliary layer 227a-1 arranged below the first upper emission layer 227b-1, a second upper auxiliary layer 227a-2 arranged below the second upper emission layer 227b-2, and a third upper auxiliary layer 227a-3 arranged below the third upper emission layer 227b-3. The first to third upper auxiliary layers 227a-1, 227a-2, and 227a-3 may be formed individually and may be formed to have different thicknesses so as to compensate for the resonance distance of the light-emitting devices.

A capping layer 240 may be arranged on the first to third light-emitting devices ED1, ED2, and ED3 and the first light-receiving device PD1 having the structure described above. For example, the capping layer 240 may be arranged on the opposite electrode 230 and may be integrally formed as a single body on the entire surface of the substrate 100. The capping layer 240 may increase the reliability of the display apparatus 1 by preventing or reducing filtration of impurities, such as water or oxygen, into the display apparatus 1.

The capping layer 240 may be an organic capping layer including an organic material, an inorganic capping layer including an inorganic material, or an organic-inorganic composite capping layer including an organic material and an inorganic material. The capping layer 240 may include a carbocyclic compound, a heterocyclic compound, an amine group-containing compound, porphine derivatives, phthalocyanine derivatives, naphthalocyanine derivatives, an alkali metal complex, an alkaline earth metal complex, or a (e.g., any suitable) combination thereof. The carbocyclic compound, the heterocyclic compound, and the amine group-containing compound may be optionally substituted with a substituent including O, N, S, Se, Si, F, Cl, Br, I, or a (e.g., any suitable) combination thereof. According to one or more embodiments, the first capping layer and/or the second capping layer may each independently include an amine group-containing compound.

In one or more embodiments, an encapsulation portion may be arranged on the capping layer 240. The encapsulation portion may be arranged on the first to third light-emitting devices ED1, ED2, and ED3 and the first light-receiving device PD1 and may serve to protect the first to third light-emitting devices ED1, ED2, and ED3 and the first light-receiving device PD1 from moisture or oxygen. The encapsulation portion may include at least one inorganic encapsulation layer and at least one organic encapsulation layer. For example, the encapsulation portion may include: an inorganic layer including silicon nitride (SiNₓ), silicon oxide (SiOₓ), indium tin oxide, indium zinc oxide, or a (e.g., any suitable) combination thereof; an organic layer including polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, and/or the like), epoxy-based resin (e.g., aliphatic glycidyl ether (AGE), and/or the like), or a (e.g., any suitable) combination thereof; or a combination of inorganic layer(s) and organic layer(s).

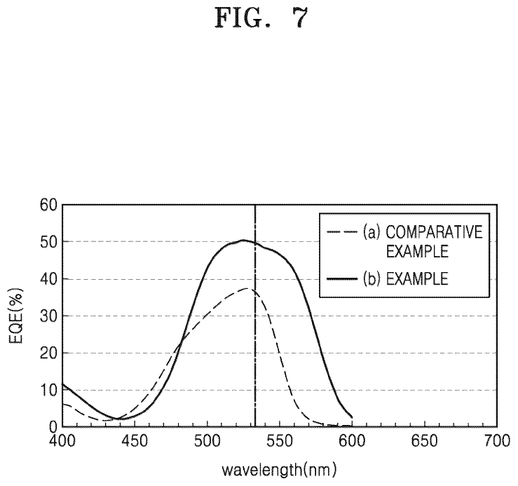

FIG. 7 is a graph showing comparison of external quantum efficiency (EQE) according to a wavelength between a display apparatus according to a comparative example and a display apparatus according to an example.

FIG. 7 is a graph showing comparison of EQE measured according to the wavelength absorbed by the light-receiving device of the display apparatus between the comparative example and the example. In FIG. 7, the horizontal axis represents the wavelength (nm) absorbed by the light-receiving device and the vertical axis represents the EQE (%) of the light-receiving device. (a) of FIG. 7 is the evaluation result for the comparative example and (b) of FIG. 7 is the evaluation result for the example. In the comparative example, the light-receiving device has a single stack structure and corresponds to a structure in which only the active layer is between the sensing electrode and the opposite electrode. In the example, the light-receiving device has a double stack structure and includes the active layer 223b-4 and the sub-charge generation layer SCGL between the sensing electrode 210-4 and the opposite electrode 230.

Referring to FIG. 7, both (e.g., simultaneously) the light-receiving device according to the example and the light-receiving device according to the comparative example (each) have an absorption center wavelength of about 530±50 nm. For example, the light-receiving device according to the example and the light-receiving device according to the comparative example may be configured to absorb and detect green light in substantially the same way.

However, referring to FIG. 7, the spectral full width at half maximum of the light-receiving device according to the example is significantly increased, compared to the light-receiving device according to the comparative example. In one or more embodiments, while the external quantum efficiency (EQE) of the light-receiving device according to the comparative example is about 36% at the absorption center wavelength, the EQE of the light-receiving device according to the example is about 50% at the absorption center wavelength. For example, the EQE of the light-receiving device according to the example is improved by about 40%, compared to the light-receiving device according to the comparative example.

As such, when the first light-receiving device PD1 has the double stack structure of the active layer 223b-4 and the sub-charge generation layer SCGL as in the display apparatus according to the example, device efficiency is superior, compared to the case of having only the active layer 223b-4.

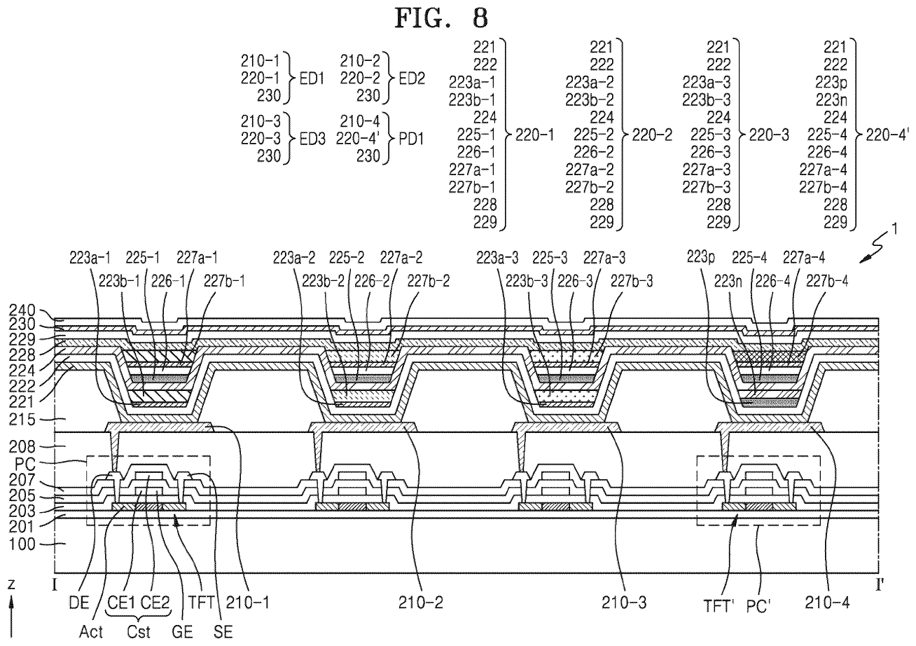

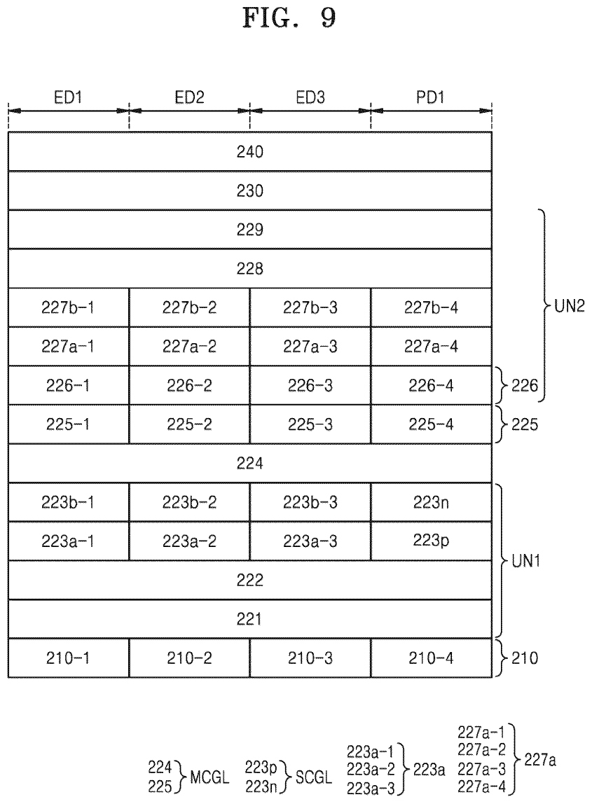

FIG. 8 is a cross-sectional view schematically illustrating a portion of a display apparatus, according to another embodiment. FIG. 9 is a conceptual diagram schematically illustrating a portion of a display apparatus, according to another embodiment. Referring to FIGS. 8 and 9, the features may each independently be the same as those described with reference to FIGS. 5 and 6, except for a first light-receiving device PD1. In FIGS. 8 and 9, the same reference numerals denote the same elements as those described with reference to FIGS. 5 and 6, and the differences will mainly described in more detail.

Referring to FIGS. 8 and 9, a first light-emitting device ED1 may include a first pixel electrode 210-1, a first intermediate layer 220-1, and an opposite electrode 230. A second light-emitting device ED2 may include a second pixel electrode 210-2, a second intermediate layer 220-2, and an opposite electrode 230. A third light-emitting device ED3 may include a third pixel electrode 210-3, a third intermediate layer 220-3, and an opposite electrode 230. The first light-receiving device PD1 may include a first sensing electrode 210-4, a fourth intermediate layer 220-4′, and an opposite electrode 230.

In this case, the first intermediate layer 220-1 may be between the first pixel electrode 210-1 and the opposite electrode 230. The second intermediate layer 220-2 may be between the second pixel electrode 210-2 and the opposite electrode 230, and the third intermediate layer 220-3 may be between the third pixel electrode 210-3 and the opposite electrode 230. The fourth intermediate layer 220-4′ may be between the first sensing electrode 210-4 and the opposite electrode 230.

Each of the first to third light-emitting devices ED1, ED2, and ED3 may be provided in a tandem structure including a plurality of emission layers. Similarly, the fourth intermediate layer 220-4′ included in the first light-receiving device PD1 may also have a double stack structure. In one or more embodiments, the fourth intermediate layer 220-4′ may include an active layer 227b-4 and a sub-charge generation layer SCGL. In this case, the sub-charge generation layer SCGL may overlap the active layer 227b-4 and may be arranged below the active layer 227b-4. For example, the sub-charge generation layer SCGL may be arranged on substantially the same layer (e.g., layer 222) as first to third lower emission layers 223b-1, 223b-2, and 223b-3 (may be arranged on), and the active layer 227b-4 may be arranged on substantially the same layer as first to third upper emission layers 227b-1, 227b-2, and 227b-3 (may be arranged on).

The active layer 227b-4 may include the same material as the active layer 223b-4 of FIG. 5, and the sub-charge generation layer SCGL may have substantially the same structure as the sub-charge generation layer SCGL of FIG. 5 and include the same material as the sub-charge generation layer SCGL of FIG. 5. For example, the sub-charge generation layer SCGL may include a p-type or kind sub-charge generation layer 223p and an n-type or kind sub-charge generation layer 223n arranged on the p-type or kind sub-charge generation layer 223p. In one or more embodiments, a fourth upper auxiliary layer 227a-4 arranged below the active layer 227b-4 may also include the same material as the fourth lower auxiliary layer 223a-4 of FIG. 5.

In other words, the first light-receiving device PD1 may have the double stack structure of the sub-charge generation layer SCGL arranged in the lower stack and the active layer 227b-4 arranged in the upper stack. Even when the first light-receiving device PD1 has a structure in which the sub-charge generation layer SCGL and the active layer 227b-4 are stacked as illustrated in FIG. 8, device efficiency may be superior, compared to the case where the first light-receiving device PD1 has a structure in which two active layers are stacked. For example, when the first light-receiving device PD1 includes a structure in which the sub-charge generation layer SCGL and the active layer 227b-4 are stacked, the sub-charge generation layer SCGL may serve to supply charges and a sufficient amount of light may reach the active layer 227b-4 arranged in the upper stack. Therefore, device efficiency may be improved.

The display apparatus according to one or more embodiments may improve display quality and may also improve the EQE and sensing sensitivity of the light-receiving device. These effects are only examples and the scope of the disclosure is not limited by such effects.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form (or provide) and details may be made therein without departing from the spirit and scope as defined by the following claims and equivalents thereof.

What is claimed is:

1. A display apparatus comprising:
a substrate comprising an emission area and a sensing area;
a light-emitting device on the substrate corresponding to the emission area; and
a light-receiving device on the substrate corresponding to the sensing area,
wherein the light-emitting device comprises a pixel electrode, a lower emission layer on the pixel electrode, an upper emission layer on the lower emission layer, and a portion of an opposite electrode on the upper emission layer, and
the light-receiving device comprises a sensing electrode, an active layer and a sub-charge generation layer on the sensing electrode, and another portion of the opposite electrode on the active layer and the sub-charge generation layer.

2. The display apparatus of claim 1, wherein the sub-charge generation layer is on the active layer.

3. The display apparatus of claim 2, wherein the lower emission layer is arranged on substantially a same layer as the active layer is arranged on, and
the upper emission layer is arranged on substantially a same layer as the sub-charge generation layer is arranged on.

4. The display apparatus of claim 1, wherein the active layer is on the sub-charge generation layer.

5. The display apparatus of claim 4, wherein the lower emission layer is arranged on a same layer as the sub-charge generation layer is arranged on, and
the upper emission layer is arranged on substantially a same layer as the active layer is arranged on.

6. The display apparatus of claim 1, wherein the sub-charge generation layer comprises:
a p-type sub-charge generation layer; and
an n-type sub-charge generation layer on the p-type sub-charge generation layer.

7. The display apparatus of claim 1, wherein the lower emission layer and the upper emission layer are patterned for each light-emitting device, and
the active layer and the sub-charge generation layer are patterned for each light-receiving device.

8. The display apparatus of claim 1, further comprising a main charge generation layer between the lower emission layer and the upper emission layer and between the active layer and the sub-charge generation layer.

9. The display apparatus of claim 8, wherein the main charge generation layer comprises:
an n-type main charge generation layer; and
a p-type main charge generation layer on the n-type main charge generation layer.

10. The display apparatus of claim 9, wherein the n-type main charge generation layer is integrally provided as a single body on an entire surface of the substrate, and
the p-type main charge generation layer is patterned for each of the light-emitting device and the light-receiving device.

11. The display apparatus of claim 8, further comprising a first hole transport layer between the pixel electrode and the lower emission layer and between the sensing electrode and the active layer,
wherein the first hole transport layer is integrally provided as a single body on an entire surface of the substrate.

12. The display apparatus of claim 11, further comprising a lower auxiliary layer between the first hole transport layer and the lower emission layer and between the first hole transport layer and the active layer,
wherein the lower auxiliary layer is patterned for each of the light-emitting device and the light-receiving device.

13. The display apparatus of claim 8, further comprising a second hole transport layer between the main charge generation layer and the upper emission layer and between the main charge generation layer and the sub-charge generation layer,
wherein the second hole transport layer is patterned for each of the light-emitting device and the light-receiving device.

14. The display apparatus of claim 13, further comprising an upper auxiliary layer between the second hole transport layer and the upper emission layer and between the second hole transport layer and the sub-charge generation layer,
wherein the upper auxiliary layer is patterned for each of the light-emitting device and the light-receiving device.

15. The display apparatus of claim 8, further comprising a buffer layer and an electron transport layer between the upper emission layer and the opposite electrode and between the sub-charge generation layer and the opposite electrode,
wherein the buffer layer and the electron transport layer are integrally provided as a single body on an entire surface of the substrate.

16. The display apparatus of claim 1, wherein the active layer comprises a p-type semiconductor compound and an n-type semiconductor compound.

17. The display apparatus of claim 16, wherein the p-type semiconductor compound comprises a compound represented by Formula 1: 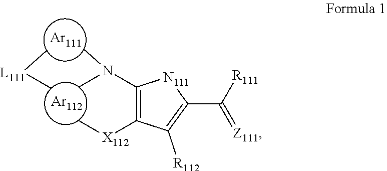
in Formula 1,
Ar₁₁₁ and Ar₁₁₂ are each independently a C₆-C₃₀ arylene group unsubstituted or substituted with at least one R₁₀ₐ or a C₃-C₃₀ heteroarylene group unsubstituted or substituted with at least one R₁₀ₐ,
X₁₁₁ is selected from among —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, and —Ge(Q₁₁₁)(Q₁₁₂)-,
X₁₁₂ and L₁₁₁ are each selected from among —O—, —S—, —Se—, —Te—, —S(═O)—, —S(═O)₂—, —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N)—,
when L₁₁₁ is selected from among —N(Q₁₁₁)-, —B(Q₁₁₁)-, —C(Q₁₁₁)(Q₁₁₂)-, —Si(Q₁₁₁)(Q₁₁₂)-, —Ge(Q₁₁₁)(Q₁₁₂)-, —(C(Q₁₁₁)=C(Q₁₁₂))-, and —(C(Q₁₁₁)=N)—, then L₁₁₁ is optionally connected to Ar₁₁₁ or Ar₁₁₂ to provide a condensed ring,
Z₁₁₁ is a C₆-C₃₀ carbocyclic group having at least one functional group selected from among C═O, C═S, C═Se, and C═Te and unsubstituted or substituted with at least one R₁₀ₐ or a C₁-C₃₀ heterocyclic group having at least one functional group selected from among C═O, C═S, C═Se, and C═Te and unsubstituted or substituted with at least one R₁₀ₐ,
R₁₁₁ and R₁₁₂ are each independently hydrogen, deuterium, a halogen, a cyano group, a nitro group, a hydroxyl group, a C₁-C₃₀ alkyl group unsubstituted or substituted with at least one R₁₀ₐ, a C₁-C₃₀ alkoxy group unsubstituted or substituted with at least one R₁₀ₐ, a C₆-C₃₀ aryl group unsubstituted or substituted with at least one R₁₀ₐ, a C₃-C₆₀ heteroaryl group unsubstituted or substituted with at least one R₁₀ₐ, a C₂-C₃₀ acyl group unsubstituted or substituted with at least one R₁₀ₐ, or a combination thereof,
R₁₀ₐ is selected from among:
deuterium (-D), —F, —Cl, —Br, —I, a hydroxyl group, a cyano group, a nitro group, or a combination thereof;
a C₁-C₆₀ alkyl group, a C₂-C₆₀ alkenyl group, a C₂-C₆₀ alkynyl group, and/or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a combination thereof and
Q₁₁ to Q₁₃, Q₂₁ to Q₂₃, Q₃₁, Q₃₂, Q₁₁₁, and Q₁₁₂ are each independently selected from among: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or a combination thereof.

18. The display apparatus of claim 17, wherein Z₁₁₁ of Formula 1 is represented by one selected from among Formulae 111A to 111F: 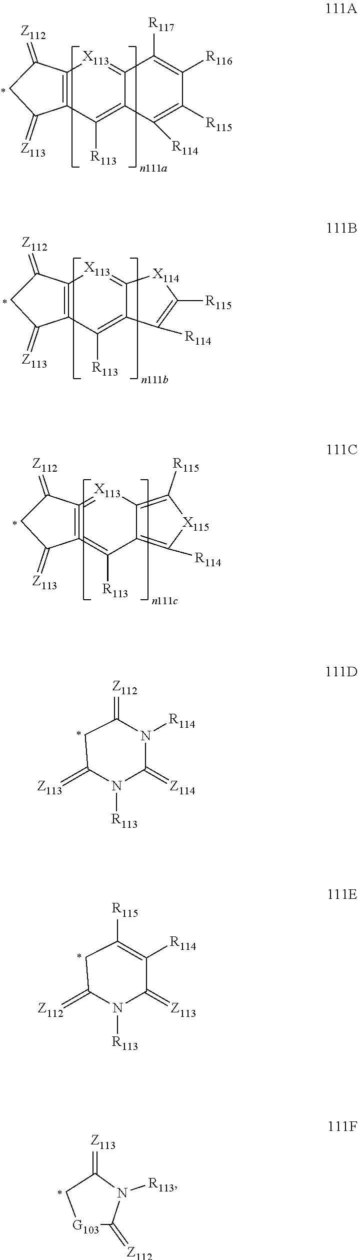
in Formulae 111A to 111F,
Z₁₁₂ to Z₁₁₄ are each O, S, Se, or Te,
X₁₁₃ is N or C(Q₁₁₃),
X₁₁₄ and X₁₁₅ are each independently O, S, Se, Te, Si(Q₁₁₁)(Q₁₁₂), or Ge(Q₁₁₁)(Q₁₁₂),
n₁₁₁ₐ to n_{111c} are each an integer from 0 to 3,
R₁₁₃ to R₁₁₇ are each independently hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a (e.g., any suitable) combination thereof, and
a definition of Q₁₁₃ is the same as a definition of Q₁₁₁.

19. The display apparatus of claim 16, wherein the n-type semiconductor compound comprises a compound represented by Formula 2 or Formula 3: 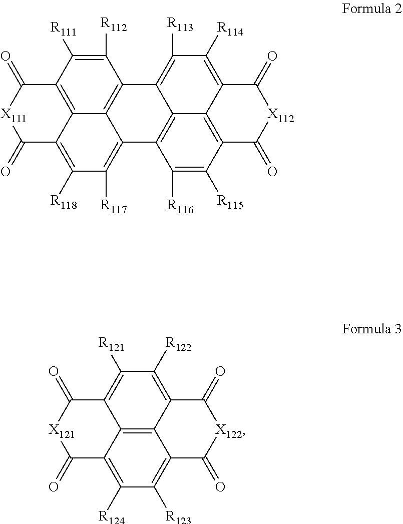
in Formula 2,
X₁₁₁ and X₁₁₂ are each independently O or NR₁₁₉, and
R₁₁₁ to R₁₁₉ are each independently hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a combination thereof,
in Formula 3,
X₁₂₁ and X₁₂₂ are each independently O or NR₁₂₅, and
R₁₂₁ to R₁₂₅ are each independently hydrogen, deuterium, halogen, a cyano group, a nitro group, a hydroxyl group, a C₁-C₃₀ alkyl group unsubstituted or substituted with at least one R₁₀ₐ, a C₆-C₃₀ aryl group unsubstituted or substituted with at least one R₁₀ₐ, a C₃-C₃₀ heteroaryl group unsubstituted or substituted with at least one R₁₀ₐ, or a combination thereof, and
in Formulae 2 and 3,
R₁₀ₐ is selected from among:
deuterium (-D), —F, —Cl, —Br, —I, a hydroxyl group, a cyano group, a nitro group, or a combination thereof;
a C₁-C₆₀ alkyl group, a C₂-C₆₀ alkenyl group, a C₂-C₆₀ alkynyl group, and/or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, and/or a C₁-C₆₀ heteroarylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₁-C₆₀ heteroaryloxy group, a C₁-C₆₀ heteroarylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or a combination thereof, and
Q₁₁ to Q₁₃, Q₂₁ to Q₂₃, Q₃₁, and Q₃₂ are each independently selected from among: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; and a C₃-C₆₀ carboxylic group, a C₁-C₆₀ heterocyclic group, a C₇-C₆₀ arylalkyl group, or a C₂-C₆₀ heteroarylalkyl group, unsubstituted or substituted with deuterium, —F, a cyano group, a C₁-C₆₀ alkyl group, a C₁-C₆₀ alkoxy group, a phenyl group, a biphenyl group, or a combination thereof.

20. The display apparatus of claim 19, wherein the n-type semiconductor compound is one selected from among compounds: 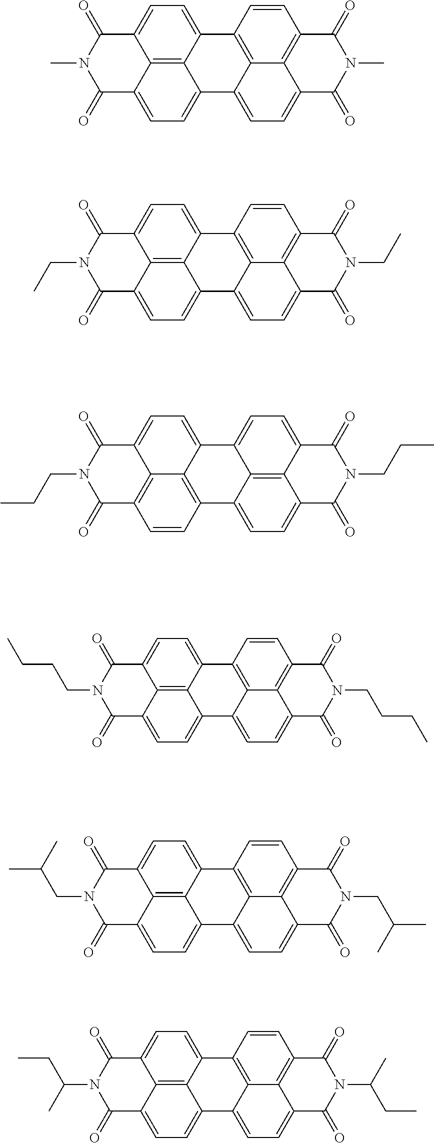 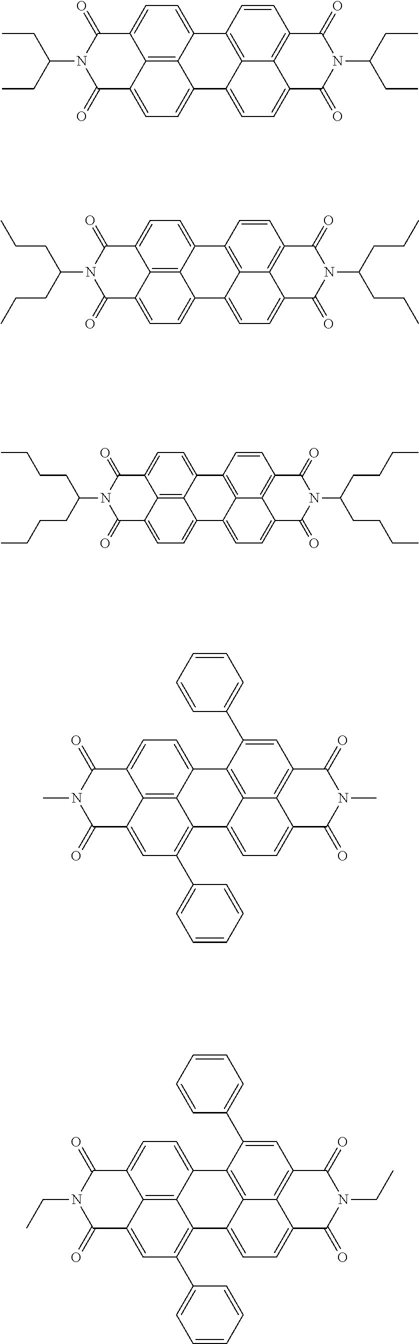 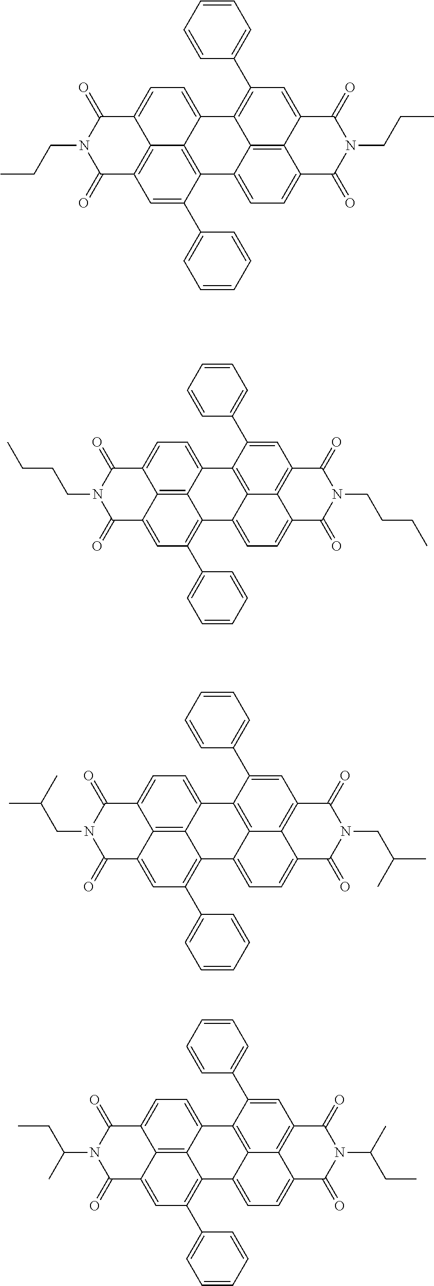 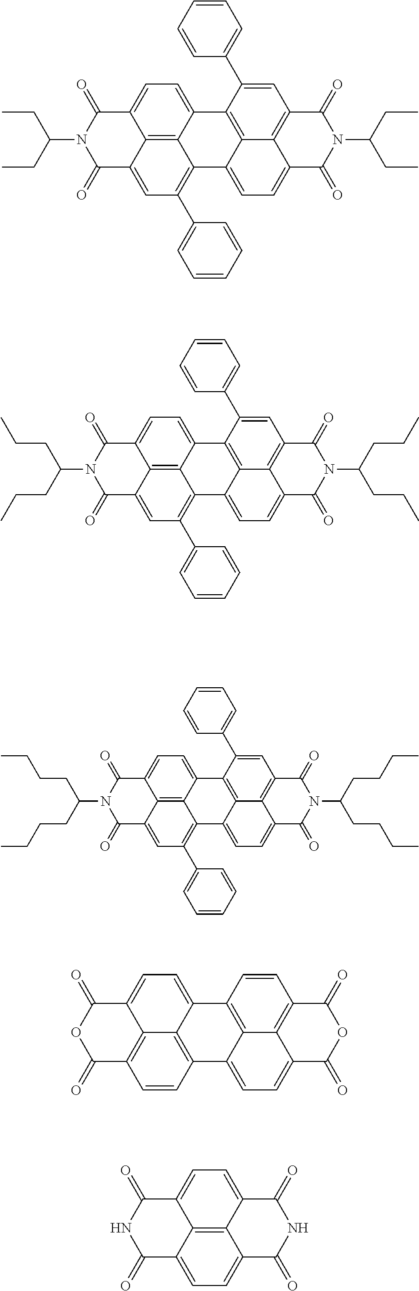 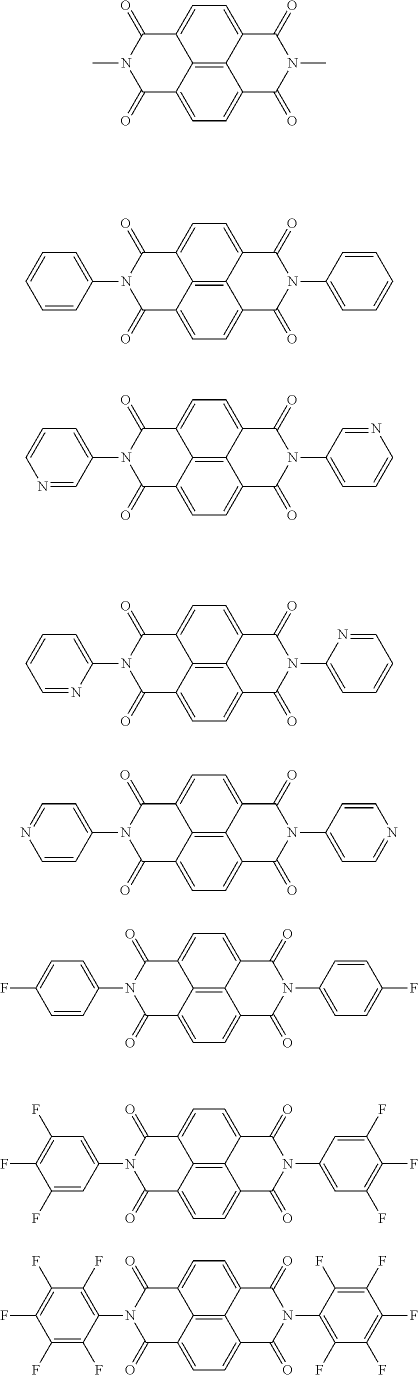 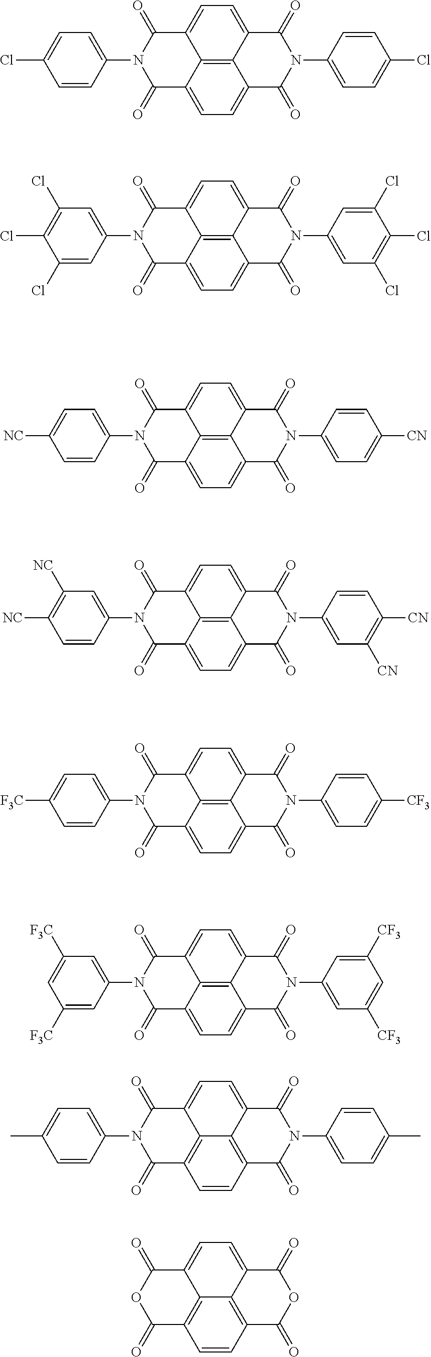 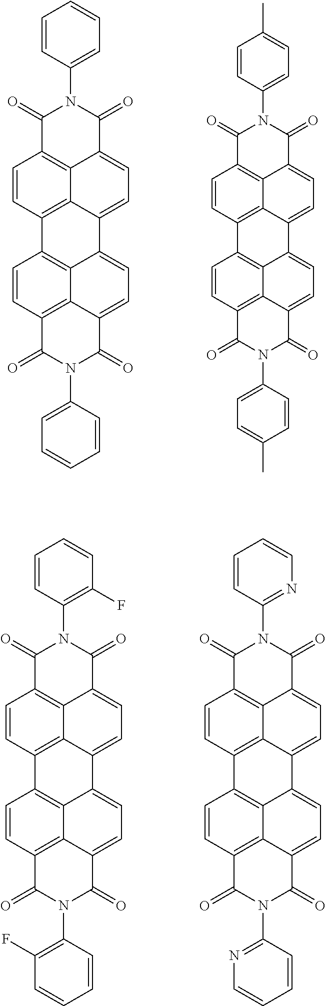 [SMILES: O=C1c2ccc3c4ccc5c6c(ccc(c7ccc(c2c37)C(=O)N1c1ccccc1)c64)C(=O)N(c1ccccc1)C5=O ; Cc1ccc(N2C(=O)c3ccc4c5ccc6c7c(ccc(c8ccc(c3c48)C2=O)c75)C(=O)N(c2ccc(C)cc2)C6=O)cc1 ; O=C1c2ccc3c4ccc5c6c(ccc(c7ccc(c2c37)C(=O)N1c1ccccc1F)c64)C(=O)N(c1ccccc1F)C5=O ; O=C1c2ccc3c4ccc5c6c(ccc(c7ccc(c2c37)C(=O)N1c1ccccn1)c64)C(=O)N(c1ccccn1)C5=O] 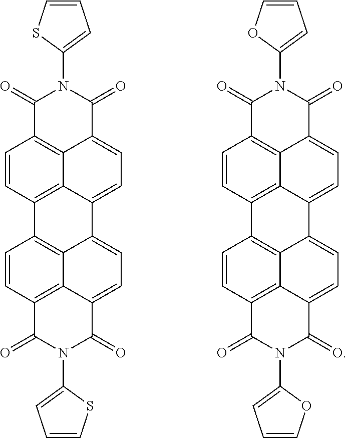 [SMILES: O=C1c2ccc3c4ccc5c6c(ccc(c7ccc(c2c37)C(=O)N1c1cccs1)c64)C(=O)N(c1cccs1)C5=O ; O=C1c2ccc3c4ccc5c6c(ccc(c7ccc(c2c37)C(=O)N1c1ccco1)c64)C(=O)N(c1ccco1)C5=O]
